(19) United States
(12) Patent Application Publication
(10) Pub. No.: US 2026/0231763 A1
(43) Pub. Date: Aug. 6, 2026

(54) TRANSIENT THERMAL MANAGEMENT OF INTEGRATED HYBRID HEAT DISSIPATION SYSTEM

(71) Applicant: SHUN-PING HUANG, Hsinchu County (TW)

(72) Inventor: SHUN-PING HUANG, Hsinchu County (TW)

(21) Appl. No.: 19/634,285

(22) Filed: Mar. 31, 2026

Related U.S. Application Data
(63) Continuation-in-part of application No. 18/113,393, filed on Feb. 23, 2023.

(51) Int. Cl. H10W 40/20; H10W 40/00; H10W 40/25; H10W 40/47

(52) U.S. Cl. CPC H10W 40/242; H10W 40/037; H10W 40/258; H10W 40/47

(57) ABSTRACT

A semiconductor package comprises a silicon die mounted on a substrate, an integrated hybrid heat spreader; a heat sink attached to the heat sink supporter, wherein the heat sink, the integrated hybrid heat spreader and the exposed major portion of the die together define a hermetic cavity-like container portion; a liquid metal preform sandwiched structure disposed inside the cavity-like container portion; a first layer of gallium-based liquid metal alloy applied between the lower surface of the liquid metal preform sandwiched structure and the silicon die; and a second layer of gallium-based liquid metal alloy applied between the upper surface of the liquid metal preform sandwiched structure and the heat sink. The semiconductor package further comprises a plurality of active cooling loops distributed evenly above silicon die and a coolant of Gallium or Galinstan inside the active cooling loops driven by the magnetohydrodynamic pumps to circulate inside the active cooling loops.

### CROSS REFERENCE TO RELATED APPLICATIONS

This application is a CIP (continuation-in-part) application of application Ser. No. 18/113,393, filed on Feb. 23, 2023, the full disclosures of which are incorporated herein by reference.

### BACKGROUND

### 1 Technical Field

The present disclosure is related to the composition, structure and application method of phase change thermal interface material (TIM) that used with Integrated Hybrid Heat Spreader (IHHS) in Integrated Hybrid Heat Dissipation System (IHHDS). A phase change TIM incorporated with supplemental active cooling can mitigate the transient thermal impacts that arouse by bursty workload esp. LLM during training and inference to enhance the silicon chip's lifespan, reliability, and overall performance.

### 2. Description of the Related Art

The rapid advancement of semiconductor miniaturization technology has led to an exponential increase in the number of transistors inside silicon chips. Consequently, extreme high power density becomes the main challenge of high-performance computing (HPC) CPU/GPU. The related thermal concerns, such as heat dissipation, and transient thermal management for the power-hungry artificial intelligence application also are stuck in dilemma between performance and power consumption.

Typical high-performance computing CPU suppliers, such as Intel and AMD, have already faced these challenges for decade and adopt Indium as thermal interface material (TIM) to reduce thermal resistance for better heat transfer. Indium has relative high bulk thermal conductivity (83 W/mK) with ductile and softness nature that provides Indium-base solder TIM (sTIM) the unique compressible feature to overcome the challenge of CTE mismatch and thermal-induced warpage among PCB substrate, CPU and Integrated Heat Spreader. As power density increases vastly, Intel started to use novel thermal package since its 12^{th} Core CPUs: Thin Die+Thin solder Thermal Interface Material (sTIM) and Thick IHS lid to improve thermal performance of high TDP CPU series as shown in FIG. 1.

Beside costly thick integrated heat spreader (IHS), complicated IHS flux reflow bonding process shown in FIG. 2 and mechanical reliability issues (voids, contact interfaces and IMCs) during thermal cycling shown in FIG. 3A, FIG. 3B, FIG. 3C, and FIG. 3D become the emerging challenges of next generation CPU. Meanwhile, the high cost of BSM (Backside Metallization) on silicon chips and heat sink (expansive Au-coating process) is another concern. That's the reason why CPU makers are eagerly looking for alternative materials and simplified assembly process to meet the emerging thermal requirements of processors in AI and Data Server applications.

Liquid metals, esp. Gallium and its alloys, become high potential candidate of thermal interface material for HPC applications due to their distinctively high thermal conductivity, non-toxic properties, conformability, resistance to hardening effects, and resistance to delamination effects. Meanwhile, the typical lidded thermal package of CPU has compatible issues with liquid metals, such as leakage and pump-out, due to the fluidity and electrical conductivity of liquid metals. Several potential material compositions and methodologies are available in the market to offer possible solutions of the aforementioned concerns and challenges. However, the complicated processes and additional costs hinder the adoption of liquid metal-based thermal interface materials.

The ultra-high power density of xPUs (CPU, DPU, GPU, NPU, and TPU) in AI and data servers applications brings the significant thermal management challenges. These issues are arisen by dynamic hotpots that generated by multi-core operations under heavy workloads, such as high intensive computing, rapid cache memory access, and high-speed I/O communications. These thermal impacts are located in the above specific areas in IC physical layout. Conventional cooling systems cannot response the transient thermal spikes promptly due to the thermal inertia of typical cooling system, such as thermal interface materials (TIM1 and TIM2), IHS lid, and cold plate).

Integrated Hybrid Heat Dissipation System (IHHDS) not only provides Integrated Hybrid Heat Spreader (IHHS), but also the composition, structure and application method of novel phase change thermal interface material (TIM) to maximize the heat dissipation. Moreover, the phase change thermal interface material incorporated with supplemental active cooling in Integrated Hybrid Heat Dissipation System (IHHDS) can perform Transient Thermal Management (TTM) to enhance the computing efficiency and performance by eliminating thermal spikes (hotspots).

### SUMMARY

The present disclosure aims to introduce an Integrated Hybrid Heat Dissipation System (IHHDS) with an innovative architecture, materials, and manufacturing technology in order to maximize heat dissipation of high-performance computing (HPC) applications in heterogeneous integration packages with large sizes, ultra-high thermal design power (TDP), and complex hybrid 2D/3D chiplet configurations. Moreover, the IHHDS offers a more reliable and efficient Transient Thermal Management (TTM) system for high-performance computing (HPC) applications.

According to one aspect of the present disclosure, the composition, structure and application method of thermal interface material (TIM) that used with Integrated Hybrid Heat Spreader (IHHS) of Integrated Hybrid Heat Dissipation System (IHHDS) that maximize the heat dissipation.

In another aspect of the present disclosure, a Thermal Interface Material (TIM) with phase change features and a Heat Sink with Active Cooling Loops that can eliminate thermal spikes (hotspots) provide Integrated Hybrid Heat Dissipation System (IHHDS) the more reliable and efficient Transient Thermal Management (TTM).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates Intel CPU's thermal improvements through package optimization.

FIG. 2 is a diagram that exhibits flux reflow process flow (steps) for a typical indium-based Solder TIM (sTIM) with vented Lid.

FIG. 3A is a diagram that shows a metallurgical summary of CPU's backside metallization through thermal cycling as determined by TEM analyses—Pre-assembly.

FIG. 3B is a diagram that shows a metallurgical summary of CPU's backside metallization through thermal cycling as determined by TEM analyses—after assembly.

FIG. 3C is a diagram that shows a metallurgical summary of CPU's backside metallization through thermal cycling as determined by TEM analyses—after moderate thermal cycling.

FIG. 3D is a diagram that shows a metallurgical summary of CPU's backside metallization through thermal cycling as determined by TEM analyses—after extensive thermal cycling.

FIG. 4 is a diagram that shows measure of the percent contact thermal resistance of total thermal resistance as a function of bond line thickness for a given example of thermal conductivity and thermal contact resistance.

FIG. 5 is a diagram that shows Indalloy 19 (51In/32.5Bi/16.5Sn, melting point: 60° C.) Thermal Resistance vs. Pressure in Solid and Liquid Phases.

FIG. 6-1A is diagram that shows Gallium-based Liquid Metal Diffuses Through Solid Solder Preforms

FIG. 6-1B is diagram that shows the cross-section view of SLH with Solid Solder Preform.

FIG. 6-2 is diagram that exhibits the Automated Process for SLH with Solid Solder Preforms and Liquid Metal.

FIG. 6-3A is diagram that shows schematic of Liquid Metal Sandwiched Pad (LMSP) TIM.

FIG. 6-3B is diagram that shows photograph of a LMSP with the size of 20 mm 20 mm.

FIG. 6-3C is diagram that exhibits melting-absorption microscopic mechanism of LMSP—the left image shows the LMSP placed between the CPU and the heat sink; the middle image presents the micropillars that deform and fill the gap under pressure; the right image displays the LM melting when heated and then absorbed by the indium film to form a solid again.

FIG. 6-4 is diagram that exhibits SLH with compressible TIM which has patterned pillars on both sides.

FIG. 6-5A is exhibited as phase diagram of Gallium—Indium alloy.

FIG. 6-5B is the diagram that Indium Corp. exhibits assembly process for High-Performance Phase Change Metal TIMs.

FIG. 6-6A, FIG. 6-6B, and FIG. 6-6C are the diagrams that Intel exhibits assembly process procedures for High-Performance Phase Change Metal TIMs in patent US 20200098661A1 [Liquid Metal TIM with STIM-like Performance with No BSM and BGA Compatible].

FIG. 6-7A is phase diagram of Ga—In binary metal. p₁ and p₃ correspond to the liquidus temperature of 70° C. and the solidus temperature of 15.5° C. for Ga_{0.50}In_{0.50}. The l and m are intersectional points between the liquidus line/solidus line and isothermal lines (30° C.), respectively.

FIG. 6-7B is phase diagram of Ga-In-Sn ternary metal. q₁ and q₃ correspond to the liquidus temperature of 70° C. and the solidus temperature of 15.5° C. for Ga_{0.40}In_{0.28} Sn_{0.32}.

FIG. 6-8A is a diagram that shows DSC heating curves for different metals from 15° C. to 105° C. @ 2° C./min. There are two peaks in the DSC curves for BMs and TM, corresponding to the two stages of the phase transitions. “endo” indicates “endothermal”.

FIG. 6-8B is a diagram that exhibits enlarged part of the DSC heating curves in the second melting stage, and the enthalpy of fusion (latent heat) can be calculated from the integration of the shadowed areas. “endo” indicates “endothermal”.

FIG. 6-8C is a diagram that shows the effective latent heat (columns) and thermal conductivity (dots) of different metals. Here, the effective latent heat is the enthalpy.

FIG. 6-9 is a diagram that shows the Ga-In-Sn ternary metal phase diagram with liquidus (isotherms) projection lines (20° C.-200° C.).

FIG. 6-10A is the diagram that Intel exhibits Intel 11^{th} Gen CPU, Alder Lake SOC/Platform Power Limiting Knobs Options Visual.

FIG. 6-10B is the diagram that Intel exhibits Intel Adaptive Boost Technology of 11^{th} Gen Intel Core i9 K and KF.

FIG. 6-11A is the diagram that John Vetrovec of Aqwest LLC exhibits Innovative heat sink with coolant flow maintained by MHD effect in paper [Quasi-Passive Heat Sink for High-Power Laser Diodes].

FIG. 6-11B is the diagram of a cross-section view of Active Heat Sink for High-Power electronics as disclosed in US Patent Publication US20120273164A1.

FIG. 6-11C is a diagram that explains MHD pump configuration.

FIG. 6-12 is a table that exhibit the trigger timing control of MHD pump.

FIG. 7-1 is a schematic diagram illustrating the cross-section view of IHHDS for monolithic silicon die with protruded part of Heat Sink, Integrated Hybrid Heat Spreader (IHHS) design and hybrid bonding method.

FIG. 7-2 is a schematic diagram illustrating the cross-section view of IHHDS that Integrated Hybrid Heat Spreader (IHHS) and a new liquid metal sandwiched TIM located between a monolithic silicon die with hotspots and Heat Sink.

FIG. 7-2-1 is a schematic diagram illustrating the top view A-A′ of Integrated Hybrid Heat Spreader (IHHS) for monolithic silicon die with hotspots shown in FIG. 7-2.

FIG. 7-2-2A and FIG. 7-2-2B are the diagrams that exhibit central exposed die through area 725*configuration.

FIG. 7-2-3A is a brief diagram for the schematic diagram of FIG. 7-2.

FIG. 7-2-3B, and FIG. 7-2-3C are the explanation drawings for elements 728 and 727 in FIG. 7-2-3A.

FIG. 7-2-3D is the cross-section view of silicon chip backside bonding area (with hotspot) in central exposed die through area 725*.

FIG. 7-3 is a schematic diagram illustrating the cross-section view of IHHDS that Integrated Hybrid Heat Spreader (IHHS) and a new liquid metal sandwiched PCM TIM located between a monolithic silicon die with hotspots and Heat Sink with liquid metal active cooling loops.

FIG. 7-3-1 is a schematic diagram illustrating the top view A-A′ of Integrated Hybrid Heat Spreader (IHHS) for monolithic silicon die and active cooling loops configuration shown in FIG. 7-3.

FIG. 7-3-2 is a schematic diagram illustrating the center cross-section view C-C′ of Integrated Hybrid Heat Spreader (IHHS) for monolithic silicon die and active cooling loops configuration shown in FIG. 7-3.

FIG. 7-3-3 is a schematic diagram illustrating the partial cross-section view B-B′ of MHD pump and active cooling loops that exhibited in FIG. 7-3-2.

FIG. 8-1A is a diagram to show assembly STEP 1 of a new liquid metal sandwiched TIM.

FIG. 8-1B is a diagram to show assembly STEP 2 of a new liquid metal sandwiched TIM.

FIG. 8-2 is a diagram that show composition structure of a new PCM (phase change metal) TIM preform for binary metal and ternary metal.

FIG. 9-1 is a schematic diagram illustrating the cross-section view of IHHDS for chiplet heterogeneous integration with protruded parts of Heat Sink, Integrated Hybrid Heat Spreader (IHHS) design and hybrid bonding method.

FIG. 9-2 is a schematic diagram illustrating the cross-section view of IHHDS that Integrated Hybrid Heat Spreader (IHHS) and a new liquid metal sandwiched TIM located between multiple silicon dies (chiplet) and Heat Sink.

FIG. 9-2-1 is a schematic diagram illustrating the top view A-A′ of Integrated Hybrid Heat Spreader (IHHS) for multiple silicon chips (chiplet) with hotspots shown in FIG. 9-2.

FIG. 9-2-2 is a schematic diagram illustrating the top view A-A′ of Integrated Hybrid Heat Spreader (IHHS) for chiplet heterogeneous integration with hotspots and the isolated grid bars on thin flexible IHHS foil shown in FIG. 9-2.

FIG. 9-2-3A is a brief diagram for the schematic diagram of FIG. 9-2.

FIG. 9-2-3B, FIG. 9-2-3C are the explanation drawings for elements 928 and 927 in FIG. 9-2-3A.

FIG. 9-2-3D is the cross-section view of bonding area in central exposed die through area 925*.

FIG. 9-3 is a schematic diagram illustrating the cross-section view of IHHDS that Integrated Hybrid Heat Spreader (IHHS) and a new liquid metal sandwiched PCM TIM located between multiple silicon dies (chiplet) with hotspots and Heat Sink with liquid metal active cooling loops.

FIG. 9-3-1 is a schematic diagram illustrating the center cross-section view C-C′ of Integrated Hybrid Heat Spreader (IHHS) for multiple silicon chips (chiplet) with hotspots shown in FIG. 9-3.

FIG. 9-3-2 is a schematic diagram illustrating the partial cross-section view B-B′ of MHD pump and active cooling loops that exhibited in FIG. 9-3-1.

FIG. 10-1, FIG. 10-2, FIG. 10-3, FIG. 10-4, FIG. 10-5-1, FIG. 10-5-2, FIG. 10-6, FIG. 10-7, FIG. 10-8, and FIG. 10-9 are schematic diagrams illustrating the assembly process that a thin IHHS and a new liquid metal sandwiched TIM of IHHDS that attach toward monolithic silicon chip package.

FIG. 11-1, FIG. 11-2, FIG. 11-3-1, FIG. 11-3-2, FIG. 11-3-3, FIG. 11-4, FIG. 11-5-1, FIG. 11-5-1A, FIG. 11-5-2, FIG. 11-5-2A, FIG. 11-5-3, FIG. 11-5-3A, FIG. 11-6, FIG. 11-7, FIG. 11-8, and FIG. 11-9 are schematic diagrams illustrating the assembly process that a thin IHHS and a new liquid metal sandwiched TIM of IHHDS that attach toward heterogeneous integration silicon chips package.

FIG. 12-1, FIG. 12-2, FIG. 12-3, and FIG. 12-4 are schematic diagrams illustrating the bottom-up assembly process of a new liquid metal sandwiched PCM TIM that attach toward monolithic silicon chip with IHHS package.

FIG. 13-1, FIG. 13-2, FIG. 13-3, and FIG. 13-4 are schematic diagrams illustrating the bottom-up assembly process of a new liquid metal sandwiched PCM TIM that attach toward heterogeneous integration silicon chips with IHHS package.

### DETAILED DESCRIPTION OF THE PREFERRED EMBODIMENT

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatial relative terms, such as “beneath.” “below,” “lower,” “above,” “upper” and the like, may be used herein for ease of description to describe one element or feature's relationship to another element(s) or feature(s) as illustrated in the figures. The spatial relative terms are intended to encompass different orientations of the device in use or operation in addition to the orientation depicted in the figures. The apparatus may be otherwise oriented (rotated 90 degrees or at other orientations) and the spatial relative descriptors used herein may likewise be interpreted accordingly.

Thermal Interface Materials (TIMs) play more important role in the overall thermal management and their bulk material characteristics are also the bottlenecks of heat dissipation. The interface contact resistance (R_{c}) and bonding/mating quality between TIMs and mating substrates (such as silicon dies and heatsink) are essential to the reliability of whole heat dissipation system, esp. high power-density applications. Therefore, the novel heat dissipation solution with novel architecture and materials is necessary for the thermal management of emerging high power density high performance computing (HPC) applications in heterogeneous integration.

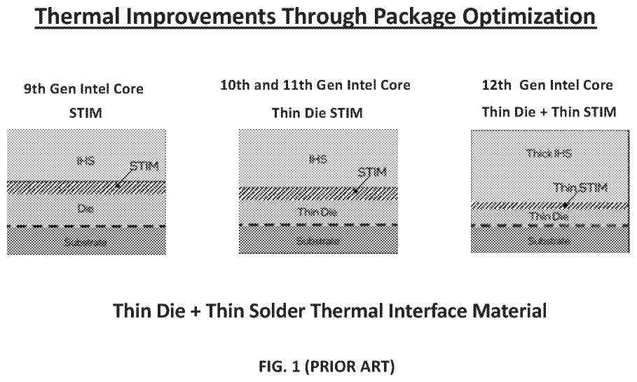

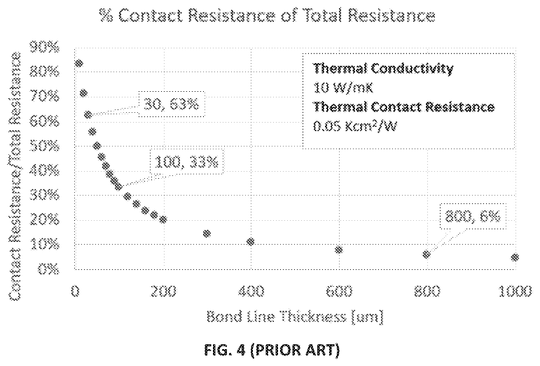

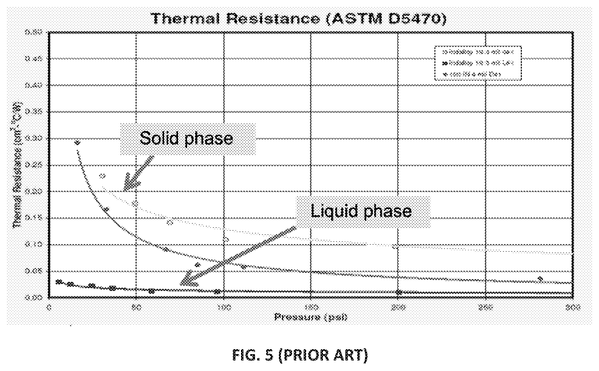

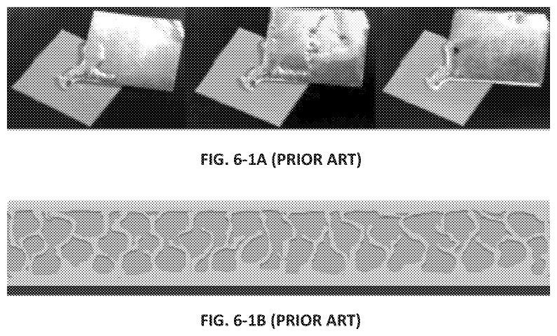

Liquid metals show significant promise in thermal interface material application due to their distinctively high thermal conductivity, non-toxic properties, conformability, resistance to hardening and delamination effects. Moreover, liquid state liquid metal can provide good adhesion and excellent wettability between contact interfaces (i.e. good interface thermal contact resistance, R_{c}). As shown in FIG. 4, thermal contact resistance (R_{c}) of thin liquid metal is the primary contributor to the overall thermal resistance as BLT (Bonding Line Thickness) is getting thinner. Low melting point liquid metal has excellent wettability because its liquid state during process period and its liquid-like nature conforms to any surface imperfection by filling gaps and micro-cracks on the surface. As shown in FIG. 5, liquid state Indalloy 19 (product of Indium corp., 51In/32.5Bi/16.5Sn, melting point: 60° C.) has better overall thermal resistance than solid state Indalloy 19 and even pure Indium. Meanwhile, the low thermal resistance of liquid state Indalloy 19 is not affected by pressure. Therefore, it implies that high thermal conductivity TIM (such as Indium-based solder TIM) with thin liquid metal contact interfaces may not need the high thermal-mechanical stress on silicon die. It is not necessary to adapt a thick IHS such as Intel latest solder TIM configuration did (shown in FIG. 1).

Furthermore, liquid metal TIMs with low melting point do not require gold-coating or other costly backside metallization (BSM) to mate with silicon dies and heat sink. Meanwhile, there is no need to apply the reflow process at the mating contact interface and to utilize the flux to remove the oxide consequently. Liquid metal TIMs become increasingly popular in various segments of the semiconductor industry, especially thermal interface materials in gaming consoles (such as PS5) and gaming laptops (such as ASUS ROG series notebook).

Liquid metals do not evaporate and cannot be inhaled. They are both thermally and electrically conductive, requiring containment and insulation for nearby components. A barrier or dam to prevent leakage can be made from various materials, such as epoxies, polymers, and soft, compressible foams. Those materials must be non-conductive and reliable. But this barrier or dam will take partial space and reduce the heat transfer rate. Another issue of liquid metals is oxidation, especially when they are exposed to very low temperatures. This can cause thermal performance degradation for the liquid metal TIMs. Moreover, handling liquid state liquid metal in cooling system assembly is less efficient and more complex due to its low viscosity, high surface tension and rapid oxidation. The erosion effect between Gallium and metals is serious challenge and needs extra cost to prevent.

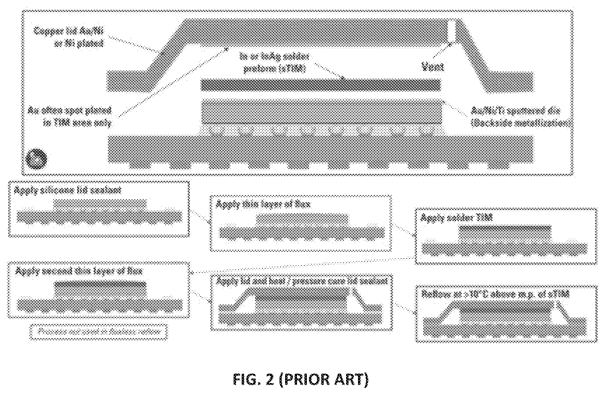

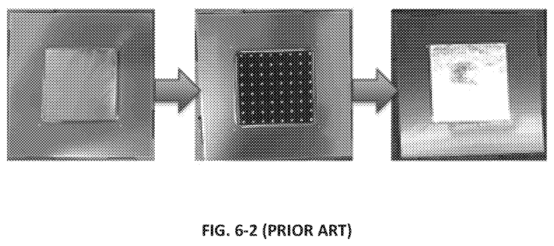

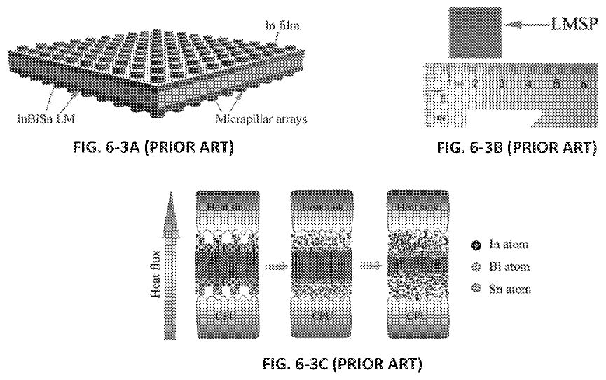

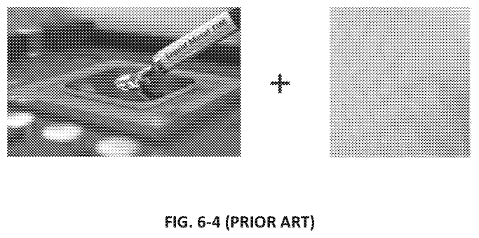

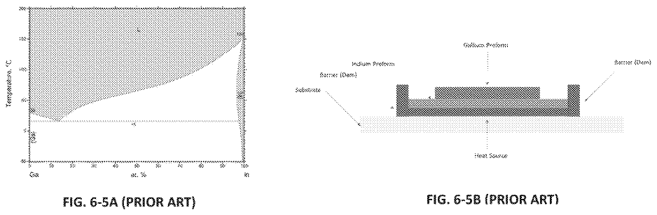

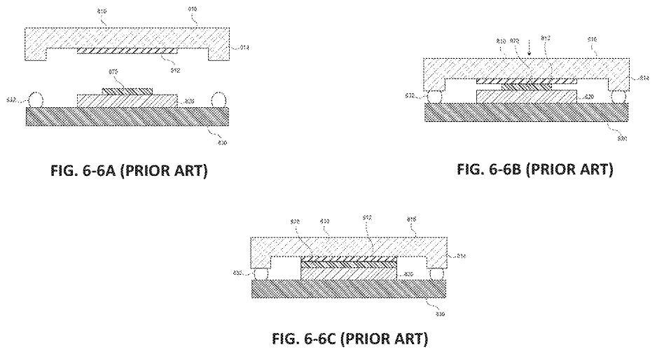

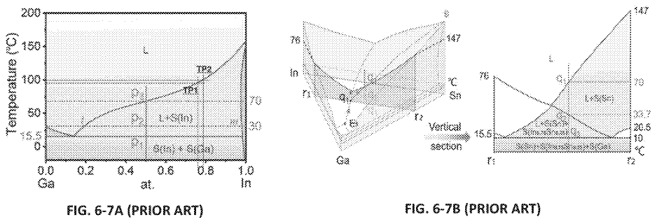

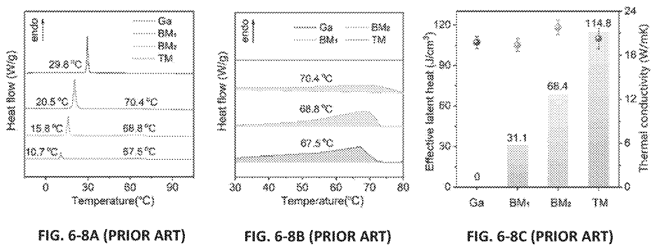

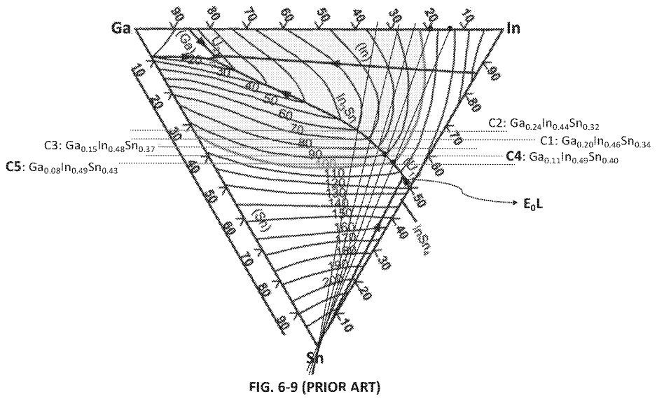

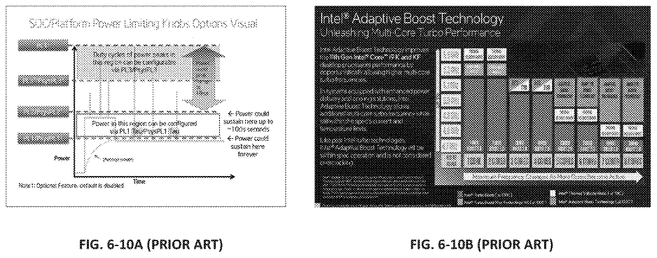

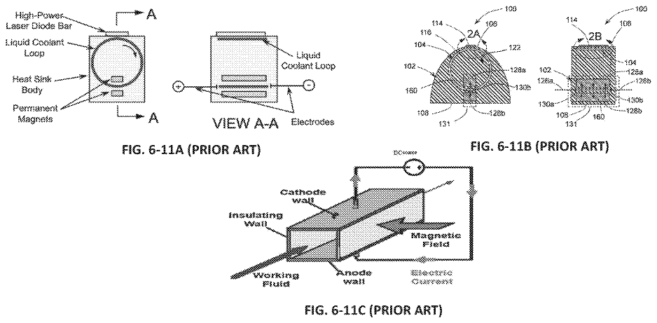

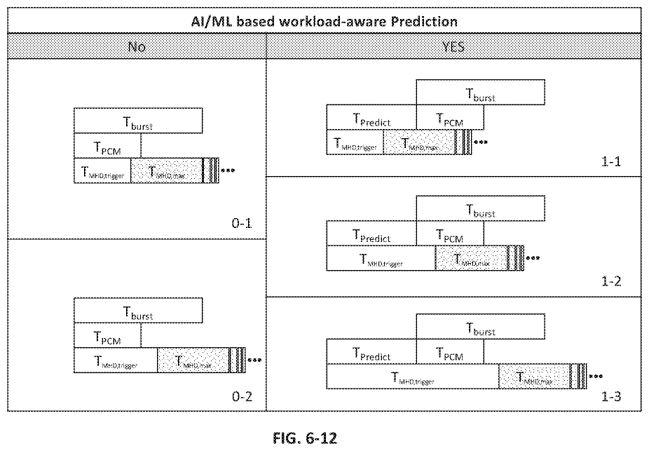

Indium Corp. proposes m2TIMs product, which forms SLH (Solid Liquid Hybrid) TIM during chip assembly, as shown in FIG. 6-1A, and FIG. 6-1B. This SLH TIM combines Gallium (liquid state above 30° C.) and solid solder Indium preform during chip assembly with additional procedures shown as below: First, Gallium (in syringe package) is applied to a heat source (silicon die) by a dispensing or jetting process (dot pattern shown in FIG. 6-2). Then, a pick-and-place machine positions a solid Indium solder preform on top of silicon die accordingly. This Indium solder preform should be highly soluble in Gallium because the mutual miscibility between Gallium and Indium. Allowing the Gallium to penetrate the grain boundaries and form the SLH. Additional liquid metal could be applied on the top of solid Indium Preform to form liquid metal sandwiched TIM (shown in FIG. 6-1B).

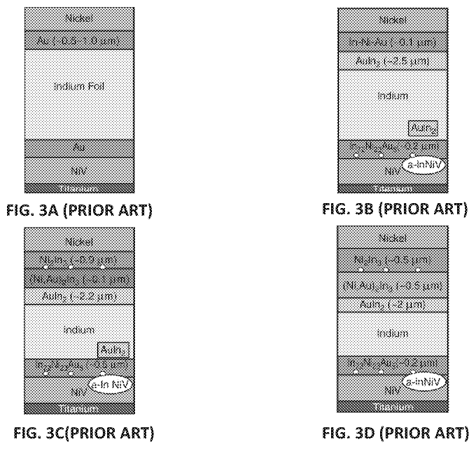

Huwei Technologies Co., Ltd. introduces Field's metal (In:Bi:Sn=51:32.5:16.5, melting point: 62° C.) instead of Gallium and an improved form of a liquid metal (LM)/Indium film/LM sandwiched pad (liquid metal sandwiched pad, LMSP) as an efficient TIM for cooling SoC of mobile phone. This sandwich-like structure is designed to prevent liquid leakage and oxidation of Gallium (Field's metal does not contain Gallium), Additionally, micropillar arrays are fabricated on both sides of liquid metal sandwiched pad to enhance the wettability and mating quality between TIM and surfaces of CPU and Heat sink shown in FIG. 6-3A, 6-3B, and 6-3C. Furthermore, m2TIMs of Indium Corp. also has similar approach with Huwei, the compressible Indium solder preform has micropillar patterns on both sides that shown in FIG. 6-4.. No matter the patterned micropillar on Field's metal or Indium solder TIM preform, it all needs additional complicated process and extra cost. The volume change of Gallium or Field's metal during phase transition will cause the unexpected concern in mechanical reliability because the potential voids or gap between liquid metals and Indium solder preform may be generated during thermal cycling.

Indium Corp. further introduces Ga-In binary metal (phase change metal, PCM) in its conference paper, “High-Performance Phase Change Metal TIMs” shown in FIG. 6-5A and FIG. 6-5B. To overcome Gallium's easy-to-oxidize liability and thermal degradation, Indium Corp. takes advantage of “solid state+solid state” HVM assembly process (FIG. 6-5B). Meanwhile, Intel also shows similar approach in its US Patent Publication US 20200098661A1 [Liquid Metal TIM with STIM-like Performance with No BSM and BGA Compatible] shown FIG. 6-6A, FIG. 6-6B, and FIG. 6-6C. Intel further points out the merits:
1) Because molten Gallium (melting point is 29.8° C.) can fill the gap and surface roughness between silicon die and Indium sTIM preform. Thin liquid state Gallium layer can enhance thermal performance due to its good wetting and high thermal contact resistance. These contact surfaces between liquid metal (Gallium) and silicon die (or heat sink) do not require gold or multi-layer metallization, such as backside metallization (BSM), nor do they utilize flux materials to remove oxides. It avoids typical high temperature and complicated sTIM bonding reflow process.
2) As solid state Gallium Preform melts, Gallium can immediately wet the surfaces of silicon die and heat sink. It avoids typical manual scrubbing process to apply liquid Gallium onto each surface of all components and turns into simplified high-volume manufacturing (HVM) assembly process.
3) Due to the compressive (malleable and soft) feature, Indium is suitable for high-volume manufacturing (HVM) compatible process, such as mixing with high thermal conductivity particles (copper or diamond), cold-rolling, and cold-pressing.

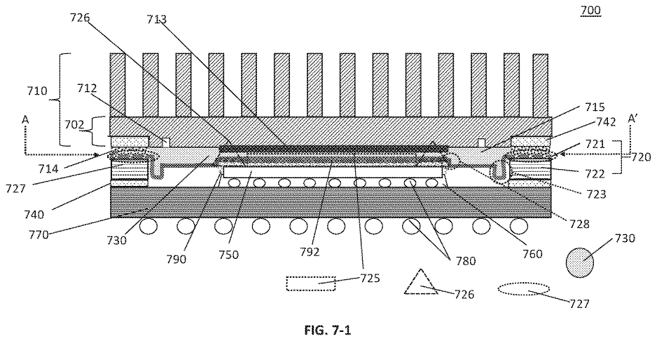

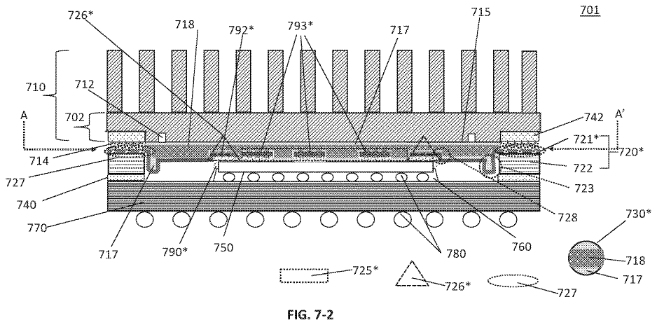

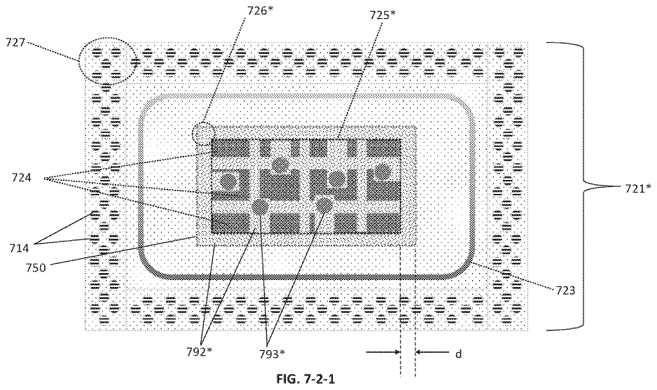

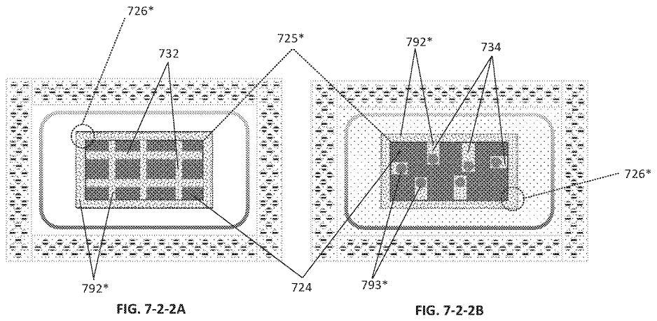

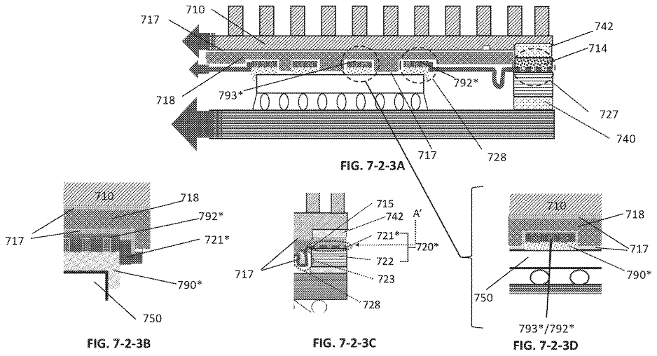

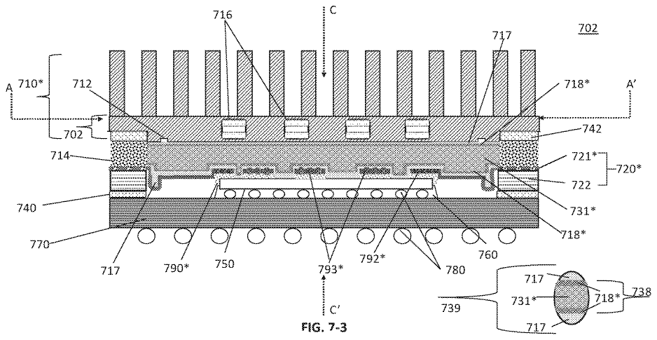

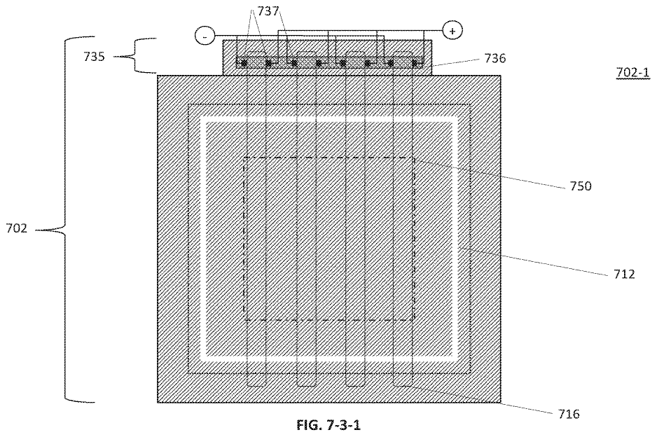

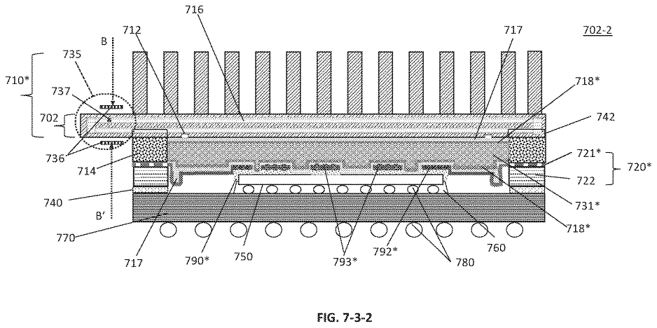

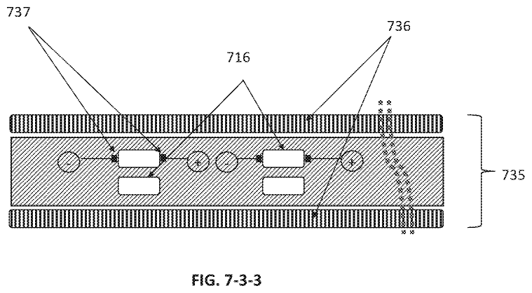

As overall package size and power density increasing, the higher junction temperature the more serious thermal induced deformation (warpage and stress), computing performance and lifespan reliability will impact to over system. Therefore, larger silicon area should be exposed, and thermal interface material should directly contact to the backside of silicon chip for more efficient heat dissipation. Accordingly, die-exposed thin flexible Integrated Hybrid Heat Spreader (IHHS,721) foil should bond to backside of bare silicon chip directly shown in FIG. 7-1.

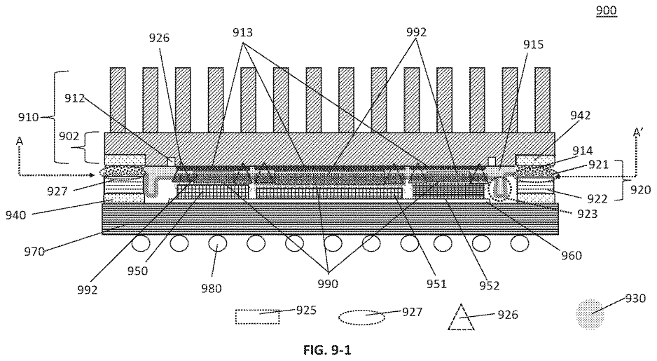

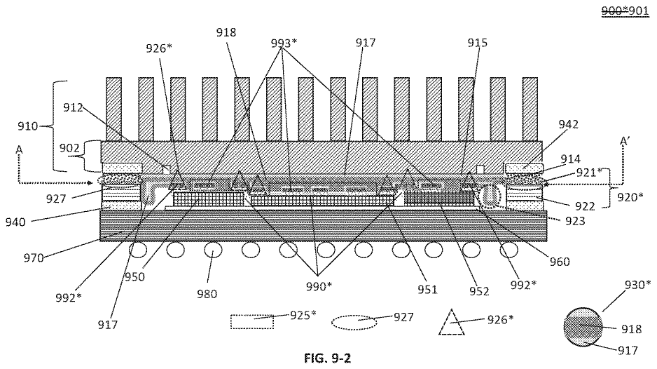

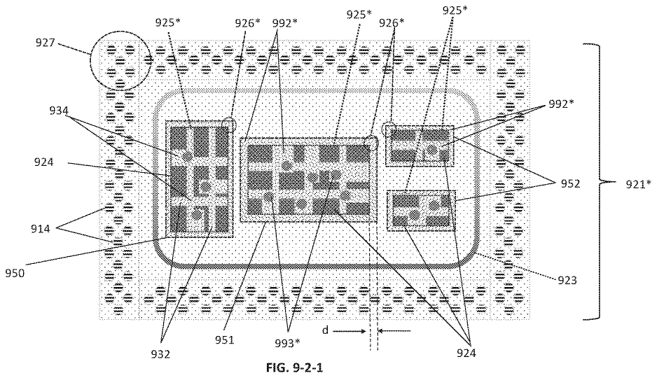

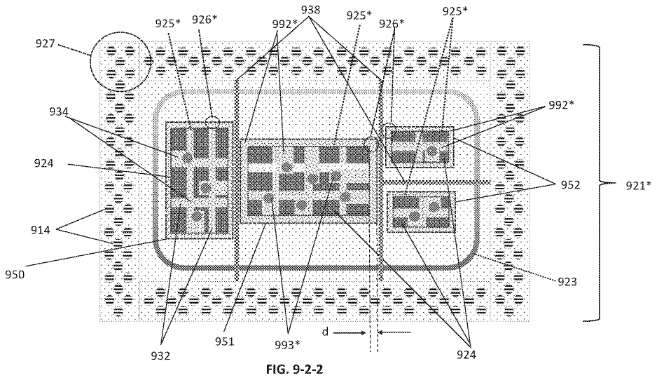

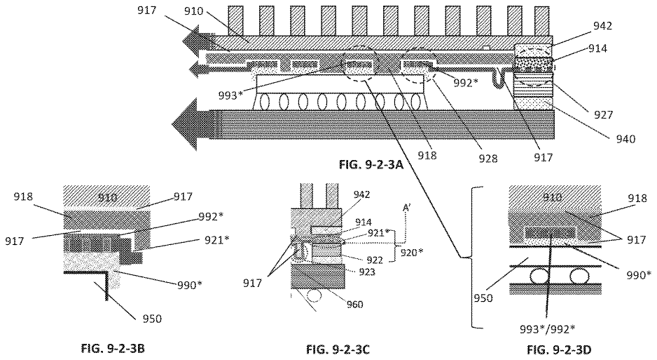

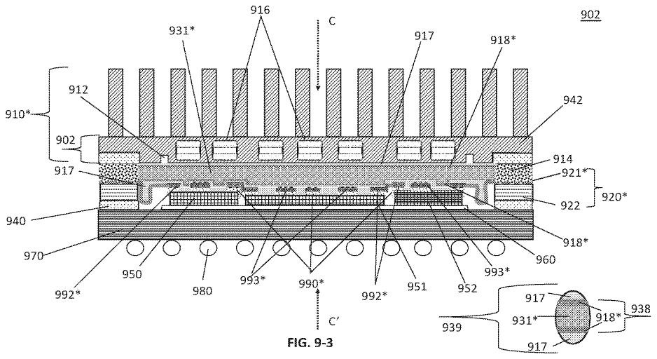

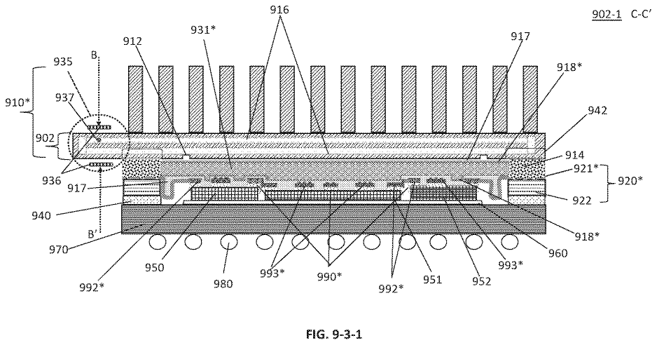

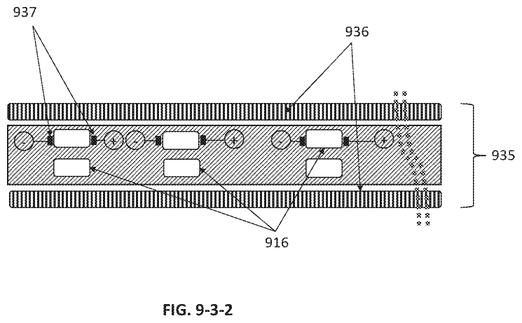

In FIG. 7-1 and FIG. 9-1, an IHHS (Integrated Hybrid Heat Spreader,720 or 920) is located between Silicon Die(s) and Heat Sink with hermetic cavity-like containment (715 or 915) to storage thermal Interface material (TIM1.5, 730 or 930). IHHS with die-exposed mechanism provides the direct-to-chip(s) contact to bare silicon die(s) (without BSM) for thermal interface material (TIM1.5, 730 or 930). Integrated Hybrid Heat Dissipation System (IHHDS) not only provides novel architecture to maximize heat transfer through shorten the heat dissipation path but also provides a unique hermetical cavity-like containment (715 in FIG. 7-2 or 915 in FIG. 9-2) that can storage any liquid state thermal interface material (TIM) inside and no concern about leakage and pump-out during thermal cycling. So, it extends the possibility of material's selection to use lower melting point liquid metal instead of Gallium, such as Galinstan or EGaInSn that is always in liquid state (no phase change) during full operation process. Therefore, it can simplify the assembly process to apply and attach liquid state TIM onto silicon dies and IHHS without any leakage concern.

As exhibited in FIG. 6-1B and 6-4, SLH (solid liquid hybrids) is formed by applying liquid state Gallium (stored in syringe) and compressive Indium Preform that has patterned micropillars on both sides to attract and contain more liquid state liquid metal due to the capillary effect between tiny micropillars (about 2 um in height and pitch). Tiny micropillar structure not only increases more contact (heat conduction) area between liquid state Gallium and Indium preform but also traps the liquid state Gallium to prevent leakage.

Intel and Indium corp. also introduce the Phase Change Metal (PCM) TIMs (Ga-In binary metal) which is comprised by solid Gallium preform and solid Indium preform (FIG. 6-5B, FIG. 6-6A, FIG. 6-6B, and FIG. 6-6C) with relatively high thermal conductivity around 40-50 W/mK, and less prone to oxidation feature. Solid Gallium preform is more stable than liquid state Gallium and easy to handle for high volume manufacturing (HVM) process.

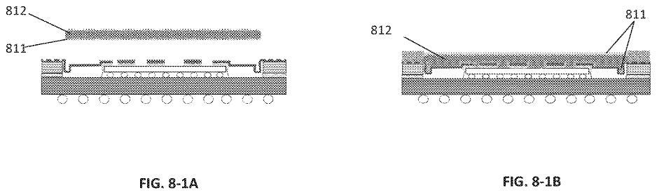

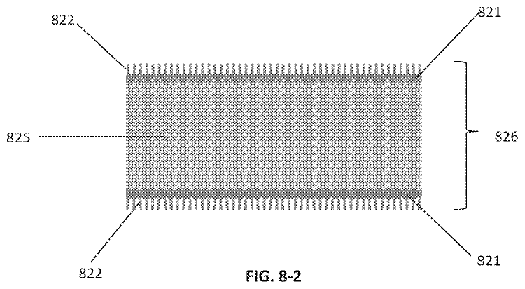

Other than Gallium, Galinstan or EGaInSn has lower melting point, less viscosity and higher fluidity. Immediately Gallium forms a stable oxide layer (Ga₂O₃) upon exposure to air, which can hinder wetting and adhesion properties. But the less oxidation formation of Galinstan and EGaInSn promotes the wetting and conforms to the rough surface. Owing to hermetic cavity-like containment (715 in FIG. 7-2), liquid state Galinstan or EGaInSn can replace solid state Gallium as thin mating interfaces with silicon die (750) and Heat Sink (710) without leakage and phase change concerns during operation. The new liquid metal sandwiched TIM, thin liquid state Galinstan or EGaInSn (811)—thick Indium Preform with double-sided micropillar patterns (812)—thin liquid state Galinstan or EGaInSn (811), is exhibited in FIG. 8-1B. Thick Indium Preform (812) may be mixed with high thermal conductivity particles (such as micro copper or diamond particles) for better thermal conductivity. In FIG. 8-1A, thick Indium Preform with double-sided micropillar patterns (812) is immersed with liquid state Galinstan or EGaInSn (811) by dipping and then attach toward silicon die and IHHS (Integrated Hybrid Heat Spreader). Then, in FIG. 8-1B, thin liquid state Galinstan or EGaInSn (811) is jetted or scrubbed onto the top of micropillar patterned surface of Indium Preform (812). This new liquid metal sandwiched TIM (730* in FIG. 7-2) has overall better thermal performance than Indium-based solder TIM and avoids the complicated solder reflow process. Meanwhile, it is not necessary to consider the additional cost about storage and shipping of solid Gallium Preform (melting point is about 30° C.).

FIG. 7-2 is a schematic diagram illustrating the cross-section view of IHHDS (701) for a silicon die. A large silicon die (750) is mounted on a PCB substrate (770) by using flip-chip solder balls (780) and underfill material (760) is infiltrated into the gap between the silicon die (750) and the PCB substrate (770). An Integrated Hybrid Heat Spreader (IHHS, 720*) comprises a thin flexible IHHS perforated foil (721*) and an IHHS foil Supporter (722). The IHHS perforated foil (721*) is comprised by a central exposed die through area (725*), a silicon die edge bonding through area (726*), a die attaching and fixing mechanism (728), a curve-shaped thermal-induced stress absorbing mechanism (723) on its lateral ends and IHHS supporter bonding through area (727). The thin flexible IHHS perforated foil (721*, about 6-25 umT) is composed of high thermal conductivity material such as copper foil or other metal coated composite foil which is made of graphite, graphene or carbon nanotube (CNT) inside.

The central die through area (725*) comprises link-and-support stripes (732, shown in FIG. 7-2-2A), hotspot contact-and-link stripes (734, shown in FIG. 7-2-2B), and the die-exposed area (724). The edge bonding through area (726*) and central die through area (725*) excluded the die-exposed area (724) of IHHS foil (721*) are covered with tiny through holes (around 0.5-1 mm diameter). The IHHS foil (721*) is bonded onto a large silicon die (750) through those tiny holes by deposition of cold spray additive manufacturing. Firstly, the metal deposition layer (792*, around 25-50 umT) is deposit through thin perforated IHHS foil (725* and 726*) onto the surface of metal deposition base layer (790* as submicron buffer layer, around 1 umT, refer to Intel paper: Cold Spray: A Disruptive Technology for Enabling Novel Packaging Thermomechanical Solutions, DOI 10.1109/ECTC32696.2021.00181) on bare silicon die. Then hotspot metal deposition layer (793*, around 100-150 umT) is deposit on corresponding area of metal deposition layer (792*) that specific hotspots located on large silicon die (750). The area of individual hotspot metal deposition layer (793*) depends on the dimension of individual hotspot.

The backside metallization (792* and 793*, where 792*+793*=200 umT can reach 20% cooling capability enhancement as above reference from Intel) onto large silicon die (750) not only can increase package the de-warpage capability during thermal cycling but also can increase the heat-spreading and cooling capability for die hotspots. The thickness of hotspot metal deposition layer (793*) depends on the thermal budget requirement of individual hotspot (the higher thermal budget, the thicker deposit metal layer). So, the abrupt hotspot burst is immediately spread to the large space of IHHS foil because of high thermal conductivity of IHHS foil materials (copper is 383 W/mK or graphene is 5000-6000 W/mK) and then directly dissipate to Heat Sink through phase change metal thermal interface material (TIM, 730*). On the other hand, the lower temperature thermal spikes outside hotspots can be dissipated directly to the phase change metal thermal interface material (PCM TIM) through the die-exposed area (724). This process helps to dissipate and reduce the heat flux that will be accumulated on the hotspots.

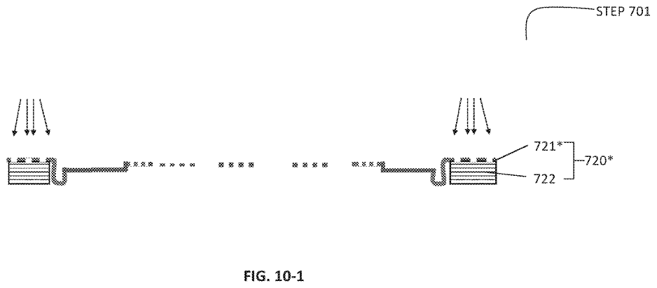

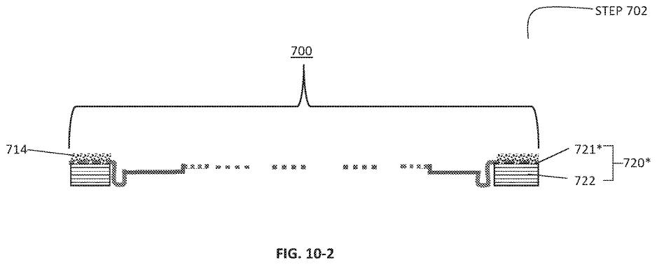

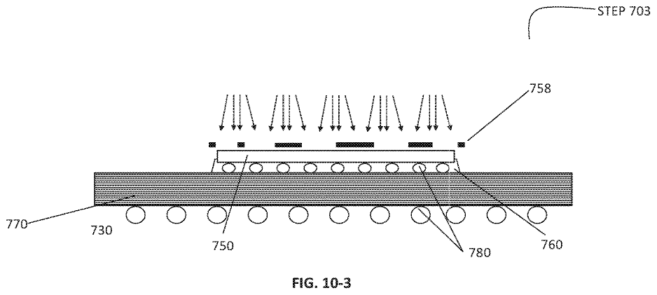

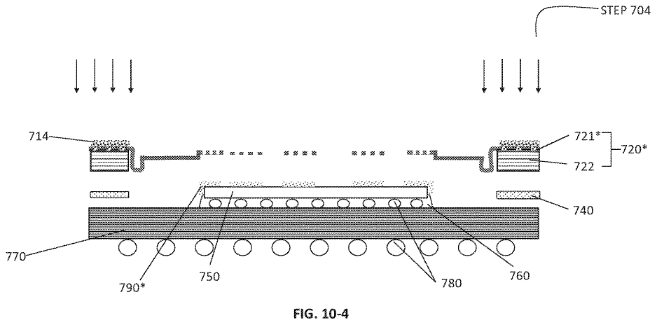

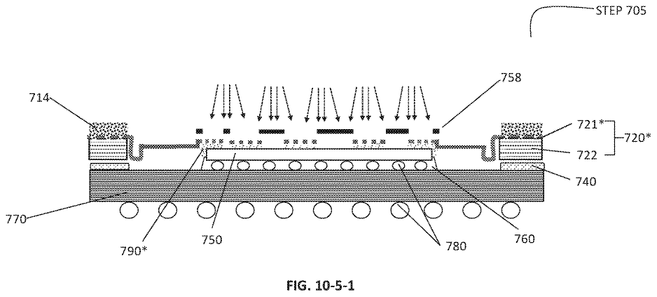

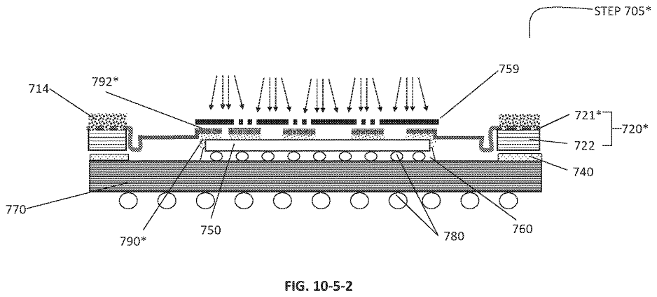

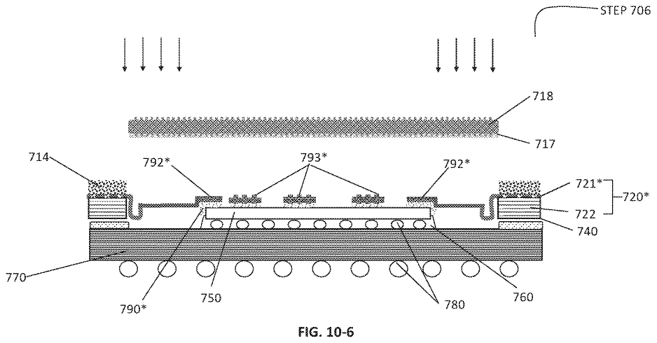

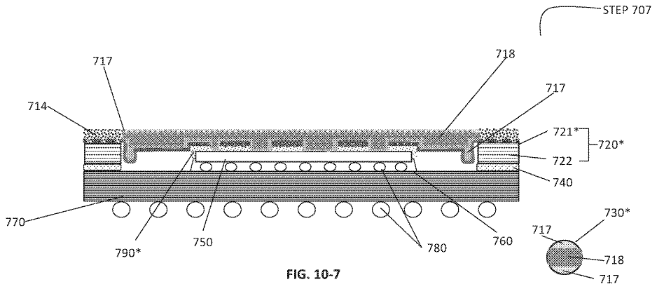

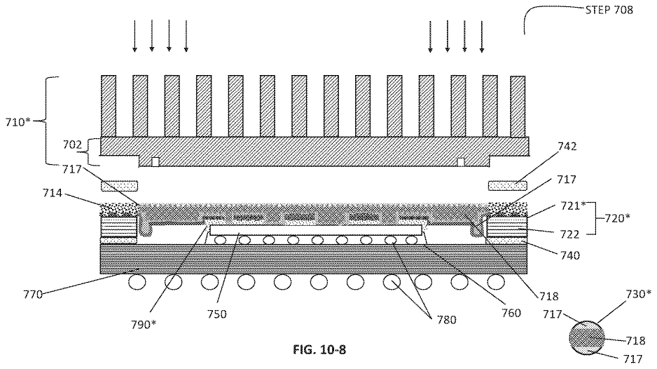

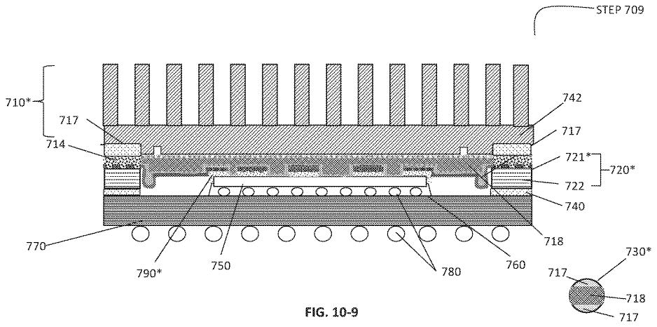

The thin flexible IHHS perforated foil (721*) is bonded to the IHHS foil Supporter (722) through the IHHS supporter bonding through area (727) by deposition of cold spray additive manufacturing. The particles injected from cold spray additive manufacturing can penetrate the flexible IHHS perforated foil (721*) and thus secure the flexible IHHS perforated foil (721*) in hermetic manner to the IHHS foil Supporter (722) and the Heat Sink Supporter layer (714) on top of the thin flexible IHHS perforated foil (721*). Therefore, the one-piece frame module (700, shown in FIG. 10-2) that comprised of the thin flexible IHHS perforated foil (721*), Heat Sink Supporter layer (714), and IHHS foil Supporter (722) is suitable to handle and position in high volume manufacturing (HVM) process.

The hermetic cavity-like containment (715), located between IHHS (720*) and Heat Sink (710), is designed to securely store liquid state liquid metal or any phase change metal TIM (730*) without the risk of leakage or pump-out issues. A thick Indium Preform with double-sided micropillar patterns (718) is immersed with liquid state Galinstan or EGaInSn (717) through a dipping process. This thick Indium Preform is 200-250 μm in its thickness and then attached to a silicon die (750) and an IHHS (721*). Then a thin liquid state Galinstan or EGaInSn (717) is applied to the top surface of the micropillar patterned Indium Preform (718) using methods such as dispensing, jetting or scrubbing. The new liquid metal sandwiched TIM (730* in FIG. 7-2) offers superior thermal performance compared to conventional Indium-based solder TIMs, while also eliminating the need for the complex solder reflow process. Meanwhile, it is not necessary to consider the additional cost related the storage and shipping of solid-state Gallium preform. The vent (712) of Heat Sink (710) can accommodate the volume changes of liquid metal TIM during thermal cycling (expansion or shrinkage).

FIG. 7-2-1 is a schematic diagram depicting the look-down view A-A′ of FIG. 7-2, the cross-section view of IHHDS (701) for monolithic silicon die. A large silicon die (750) is located at the middle of the thin flexible IHHS perforated foil (721*). A central die through area (725*) of thin flexible IHHS perforated foil (721*) is smaller than the area of the silicon die (750) and is comprised of die-exposed area (724), link-and-support stripes (732, not shown), and hotspot contact-and-link stripes (734, not shown). The edge-to-edge distance (d) of edge bonding through area (726*) is about 2-3 mm. A thin flexible IHHS perforated foil (721*) is bonded to the IHHS foil Supporter (722) through the IHHS supporter bonding through area (727) by deposition of cold spray additive manufacturing. The particles injected from cold spray additive manufacturing can penetrate the flexible IHHS perforated foil (721*) and thus secure the flexible IHHS perforated foil (721*) in hermetic manner to the IHHS foil Supporter (722) and the Heat Sink Supporter layer (714) which is on top of the thin flexible IHHS perforated foil (721*). The perforated pattern (tiny holes) of the edge bonding through area (726*) and the central die through area (725*) is densely distributed design to allow the metal deposition layer (792*) to thrust through and firmly attach the thin flexible IHHS perforated foil (721*) onto the silicon die (750) in a secure and hermetic manner. A hotspot metal deposition layer (793*) is deposit on the corresponding area of metal deposition layer (792*) that location of die hotspots. The thin flexible IHHS perforated foil (721*) is bonded to the IHHS foil Supporter (722) through the IHHS supporter bonding through area (727) by deposition of cold spray additive manufacturing.

The shape of the perforated pattern can vary, such as round holes, strips, or irregular shapes (as illustrated in FIG. 7-2-1, the example shows round holes). The perforated pattern (tiny holes) of central exposed die through area (725*) and edge bonding through area (726*) are evenly distributed on silicon backside to mitigate package warpage during thermal cycling. The thermal-induced stress absorbing mechanism (723) of the thin flexible IHHS perforated foil (721*) is located laterally between the silicon die (750) and Heat Sink Supporter layer (714).

FIG. 7-2-2A and FIG. 7-2-2B are explanation drawings for 725* of FIG. 7-2-1. The central die through area (725*) is comprised of die-exposed area (724), link-and-support stripes (732) and hotspot contact-and-link stripes (734). Those stripes are overlapped and linked with silicon die edge bonding through area (726*). Moreover, all those stripes are covered with tiny through holes that metal deposition layer (792*) penetrated through and bonded with metal deposition base layer (790*) on the silicon die. Then, a hotspot metal deposition layer (793*) is deposit on the corresponding area of metal deposition layer (792*) that location of die hotspots.

FIG. 7-2-3B, and FIG. 7-2-3C are the explanation drawings for 728 and 727 of FIG. 7-2-3A. The new liquid metal sandwiched TIM (730*, shown in FIG. 7-2), thin liquid state EGaInSn or Galinstan layer (717)—thick Indium Preform with double-sided micropillar patterns (718)—thin liquid state EGaInSn or Galinstan layer (717), can take the role as typical Indium-based solder TIM with less thermal resistance between the silicon die (750) and Heat Sink (710) and also absorb the thermal-induced CTE mismatch from different materials due to its compressive nature. In FIG. 7-2-3B the die attaching and fixing mechanism (728) for the thin flexible IHHS perforated foil (721*) is illustrated. The die attaching and fixing mechanism (728) provides the cap-like portions corresponding to the periphery of the silicon die to ensure proper alignment and fixation of the thin flexible IHHS perforated foil (721*) onto the thin metal deposition layer (790*) on the silicon die (750). In FIG. 7-2-3C, the thin flexible IHHS perforated foil (721*) is hermetically bonded to the IHHS foil Supporter (722) through the IHHS foil Supporter bonding through area (727) by deposition of cold spray additive manufacturing. This bonding process forms the Heat Sink Supporter layer (714) on top of the thin flexible IHHS perforated foil (721*).

In FIG. 7-2-3D it exhibits the detailed cross-section of bonding area in central exposed die through area 725*. The liquid metal sandwiched TIM (730*), thin EGaInSn or Galinstan layer (717)—Indium Preform with double-sided micropillar patterns (718)—thin EGaInSn or Galinstan layer (717) is located between Heat Sink (710) and hotspot metal deposition layer (793*)/metal deposition layer (792*)—IHHS foil (721*)—metal deposition base layer (790*) is securely bonded on bare silicon die (750).

FIG. 9-2 is a schematic diagram illustrating the cross-section view of IHHDS (901) for chiplet heterogeneous integration. Multiple silicon dies which include a tall chip (950), a thin and flat chip (951), and stacked dies (952) are mounted on PCB substrate (970) using flip-chip solder balls (no shown) and infiltrated with underfill (960) between the gap of multiple silicon dies (950, 951, and 952) and PCB substrate (970). An Integrated Hybrid Heat Spreader (IHHS, 920*) comprises a thin flexible IHHS perforated foil (921*) and an IHHS foil Supporter (922). The IHHS perforated foil (921*) includes serval corresponded exposed die through area (925*), serval corresponded silicon die edge bonding through area (926*), serval corresponded die attaching and fixing mechanism (928, no shown), a curve-shaped thermal-induced stress absorbing mechanism (923) on its lateral ends and IHHS supporter bonding through area (927). The thin flexible IHHS perforated foil (921*, about 6-25 umT) comprises high thermal conductivity material such as copper foil or other metal coated composite foil which made of graphite, graphene or carbon nanotube (CNT) inside.

These corresponded central die through area (925*) is composed of link-and-support stripes (932, shown in FIG. 9-2-1), hotspot contact-and-link stripes (934, shown in FIG. 9-2-1), and die-exposed area (924). The edge bonding through area (926*) and central die through area (925*) excluded the die-exposed area (924) of IHHS foil (921*) are covered with tiny through holes (tiny spots, around 0.5-1 mm diameter). The IHHS foil (921*) is bond onto silicon dies (950, 951, and 952) by deposition of cold spray additive manufacturing. Firstly, the metal deposition layer (992*, around 25-50 umT) is deposit through thin perforated IHHS foil (925* and 926*) onto the surface of metal deposition base layer (990* as submicron buffer layer, around 1 umT, refer to Intel paper: Cold Spray: A Disruptive Technology for Enabling Novel Packaging Thermomechanical Solutions, DOI 10.1109/ECTC32696.2021.00181) on bare silicon dies. Then hotspot metal deposition layer (993*, around 100-150 umT) is deposit on corresponding area of metal deposition layer (992*) that specific hotspots located on silicon dies. The area of individual hotspot metal deposition layer (993*) depends on the dimension of individual hotspot.

The backside metallization (992* and 993*, where 992*+993*=200 umT can reach 20% cooling capability enhancement as above reference from Intel) on silicon dies not only can increase package the de-warpage capability during thermal cycling but also can increase the heat-spreading and cooling capability for hotspots. The thickness of hotspot metal deposition layer (993*) depends on the thermal budget requirement of individual hotspot (the higher thermal budget, the thicker deposit metal layer). So, the abrupt hotspot burst is immediately spread to the large space of IHHS foil because of high thermal conductivity of IHHS foil materials (copper is 383 W/mK or graphene is 5000-6000 W/mK) and then directly dissipate to Heat Sink through thermal interface material (TIM, 930*). On the other hand, the lower temperature thermal spikes outside hotspots also can be dissipated directly to the thermal interface material (TIM) through die-exposed area (924). This process helps to dissipate and reduce the heat flux that will be accumulated on the hotspots.

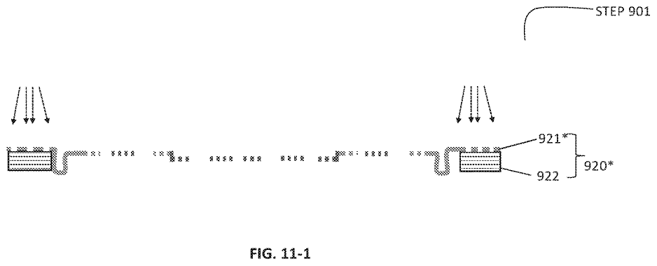

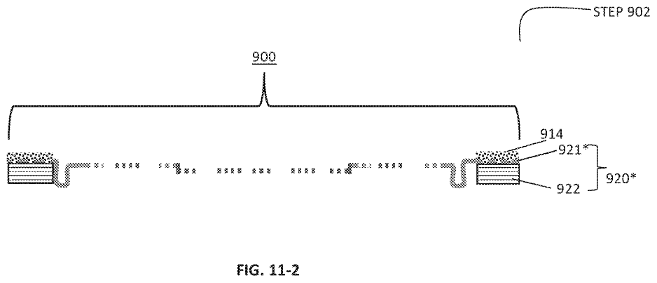

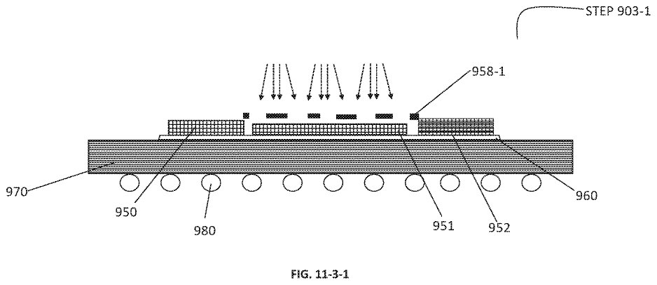

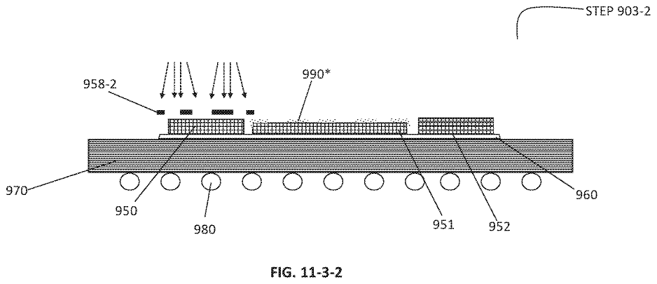

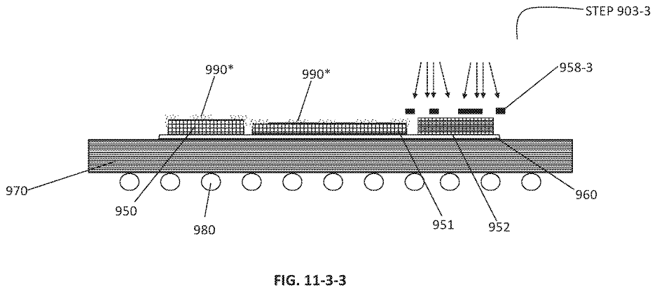

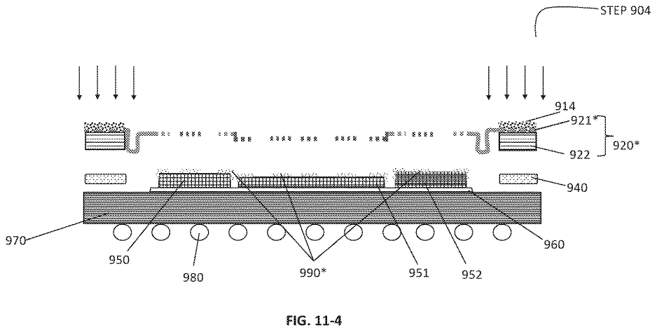

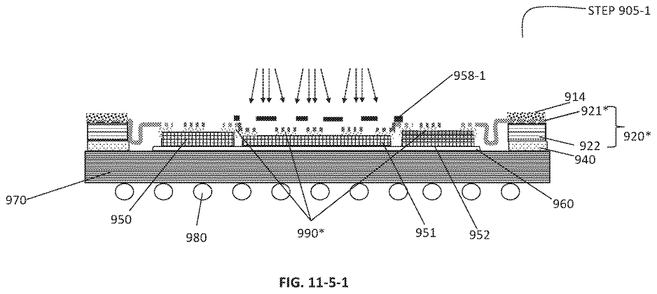

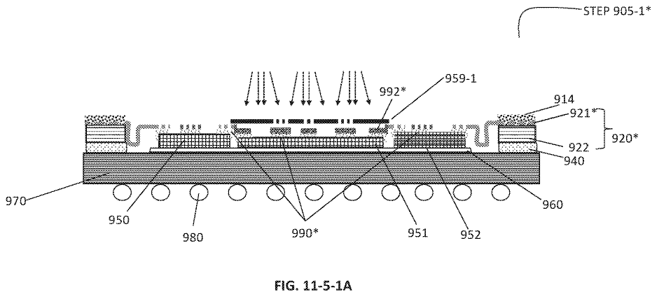

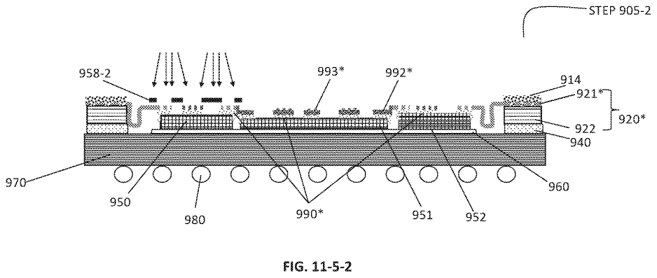

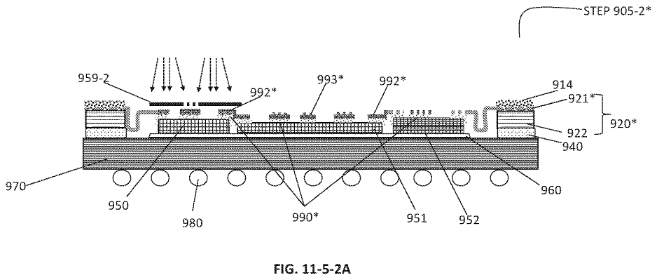

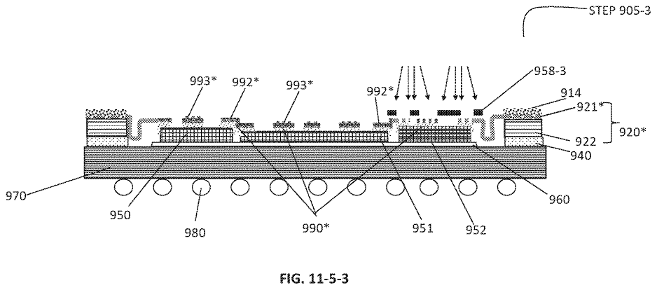

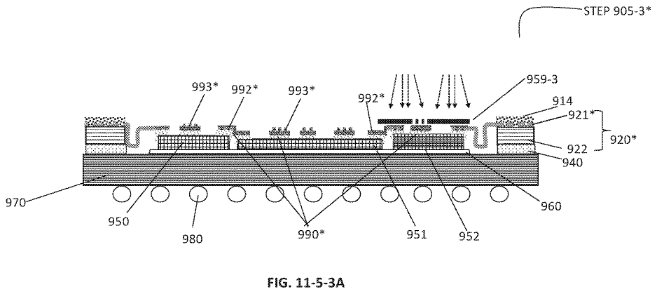

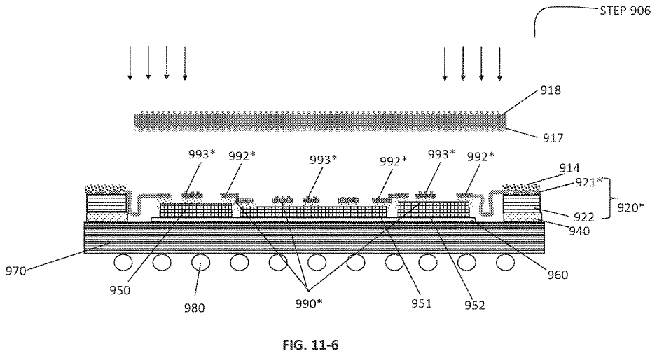

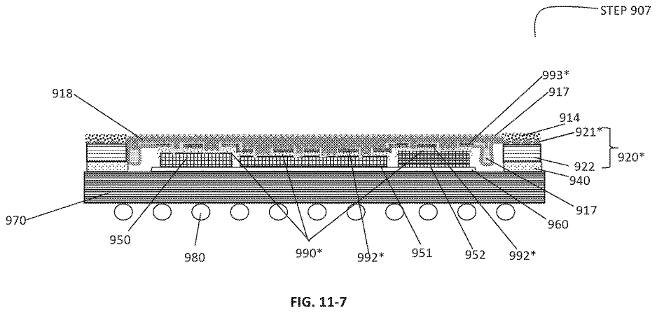

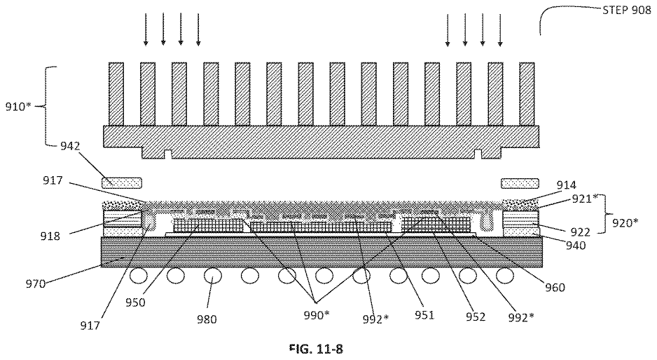

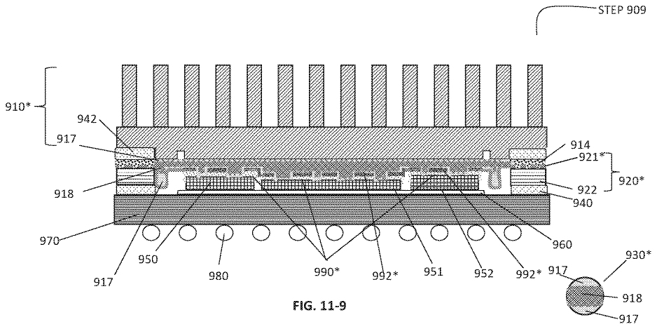

The thin flexible IHHS perforated foil (921*) is bonded to the IHHS foil Supporter (922) through the IHHS supporter bonding through area (927) by deposition of cold spray additive manufacturing. The particles injected from cold spray additive manufacturing can penetrate the flexible IHHS perforated foil (921*) and thus secure the flexible IHHS perforated foil (921*) in hermetic manner to the IHHS foil Supporter (922) and the Heat Sink Supporter layer (914) on top of the thin flexible IHHS perforated foil (921*). Therefore, the one-piece frame module (900, shown in FIG. 11-2) that comprised of the thin flexible IHHS perforated foil (921*), Heat Sink Supporter layer (914), and IHHS foil Supporter (922) is suitable to handle and position in HVM process.

The hermetic cavity-like containment (915), located between IHHS (920*) and Heat Sink (910), is designed to securely store liquid state liquid metal or any phase change metal TIM without the risk of leakage or pump-out issue. A thick Indium Preform with double-sided micropillar patterns (918) is immersed with liquid state Galinstan or EGaInSn (917) through a dipping process. This thick Indium Preform is 200-250 μm in its thickness and then attached to silicon dies and an IHHS (921*). Then a thin liquid state Galinstan or EGaInSn (917) is applied to the top surface of the micropillar patterned surface of Indium Preform (918) using methods such as dispensing, jetting or scrubbing. The new liquid metal sandwiched TIM (930* in FIG. 9-2) offers superior thermal performance compared to conventional Indium-based solder TIM, while also eliminating the need for the complicated solder reflow process. Meanwhile, it is not necessary to consider the additional cost about storage and shipping of solid state Gallium preform. The vent (910) of Heat Sink (910) can accommodate the volume changes of liquid metal TIM during thermal cycling (expansion or shrinkage).

FIG. 9-2-1 is a schematic diagram depicting the look-down view A-A′ of FIG. 9-2, the cross-section view of IHHDS (901) for chiplet heterogeneous integration. The silicon dies (950, 951, and 952) are located at the middle of the thin flexible IHHS perforated foil (921*). The individual central die through area (925*) of thin flexible IHHS perforated foil (921*) is smaller than the area of individual silicon dies (950, 951, and 952) and are comprised of die-exposed area (924), link-and-support stripes (932, not shown), and hotspot contact-and-link stripes (934, not shown). The edge-to-edge distance (d) of silicon die bonding through area (926) is about 2-3 mm. A thin flexible IHHS perforated foil (921*) is hermetically bonded to the IHHS foil Supporter (922) through the IHHS supporter bonding through area (927) by deposition of cold spray additive manufacturing. The particles injected from cold spray additive manufacturing can penetrate the flexible IHHS perforated foil (921*) and thus secure the flexible IHHS perforated foil (921*) in hermetic manner to the IHHS foil Supporter (922) and the Heat Sink Supporter layer (914) which is on top of the thin flexible IHHS perforated foil (921*). The perforated pattern (tiny holes) of the silicon die bonding through area (926*) and the central die through area (925*) is densely distributed design to allow the metal deposition layer (992*) to thrust through and firmly attach the thin flexible IHHS perforated foil (921*) onto silicon dies (950, 951, and 952) in a secure and hermetic manner. A hotspot metal deposition layer (993*) is deposit on the corresponding area of metal deposition layer (992*) that location of die hotspots. The thin flexible IHHS perforated foil (921*) is bonded to the IHHS foil Supporter (922) through the IHHS supporter bonding through area (927) by using cold spray additive manufacturing.

The shape of the perforated pattern can vary, such as round holes, strips, or irregular shapes (as illustrated in FIG. 9-2-1, the example shows round holes). The perforated pattern (tiny holes) of exposed die through area (925*) and edge bonding through area (926*) are evenly distributed on backside of silicon dies to mitigate package warpage during thermal cycling. The thermal-induced stress absorbing mechanism (923) of the thin flexible IHHS perforated foil (921*) is located laterally between silicon dies and Heat Sink Supporter layer (914).

FIG. 9-2-2 is a schematic diagram illustrating the look-down view of IHHDS (901) for chiplet heterogeneous integration with isolated grid bars (938) on thin flexible IHHS perforated foil (921*). These isolated supporter grids (938) are made which of a heat isolated material with low thermal conductivity and are attached to thin flexible IHHS perforated foil (921*). The purpose is to apply different TIMs on separated area based on the corresponded silicon dies'requirement. The approach aims to achieve the optimal overall thermal performance and avoid the thermal cross-talk between neighboring silicon dies or area. Additionally, the height of isolated supporter grids (938) is slightly higher than the height of TIMs but the same as Heat Sink Supporter layer (914) height. Consequently, the Heat Sink (910), isolated grid bars (938), and Heat Sink Supporter layer (914) together form several sub-cavity-like area that can accommodate and confine different TIMs for the corresponded silicon dies.

FIG. 9-2-3B and FIG. 9-2-3C are explanation drawings for 928 and 927 of FIG. 9-2-3A. The new liquid metal sandwiched TIM (930*, shown in FIG. 9-2), thin liquid state EGaInSn or Galinstan layer (917)—thick Indium Preform with double-sided micropillar patterns (918)—thin liquid state EGaInSn or Galinstan layer (917), can take the role as typical Indium-based solder TIM with less thermal resistance between silicon dies (950, 951, and 952) and Heat Sink (910) and also absorb the thermal-induced CTE mismatch from different materials due to its compressive nature. In FIG. 9-2-3B the die attaching and fixing mechanism (928) for the thin flexible IHHS perforated foil (921*) is illustrated. The die attaching and fixing mechanism (928) provides the cap-like portions corresponding to the periphery of the silicon die to ensure proper alignment and fixation of the thin flexible IHHS perforated foil (921*) onto the thin high thermal conductivity metal deposition layer (990*) on the silicon dies (950, 951, and 952). In FIG. 9-2-3C, the thin flexible IHHS perforated foil (921*) is hermetically bonded to the IHHS foil Supporter (922) through the IHHS foil Supporter bonding through area (927) by deposition of cold spray additive manufacturing. This bonding process forms the Heat Sink Supporter layer (914) on top of the thin flexible IHHS perforated foil (921*).

FIG. 9-2-3D it exhibits the cross-section of bonding area in exposed die through area 925*. The liquid metal sandwiched TIM (930*), thin EGaInSn or Galinstan layer (917)—Indium Preform with double-sided micropillar patterns (918)—thin EGaInSn or Galinstan layer (917) is located between Heat Sink (910) and hotspot metal deposition layer (993*)/metal deposition layer (992*)—IHHS foil (921*)-metal deposition base layer (990*) is securely bonded on bare silicon dies (950, 951, and 952).

Furthermore, Intel and Indium Corp. introduces the new Phase Change Metal (PCM) TIM as the good candidate to manage and eliminate thermal spikes potentially because its latent heat absorption. Especially Ga—In binary metal can perform continuous latent heat absorption by controlling the weight or volume mixing ratio of binary metals and its liquidus temperature (melting point) can be located between the range from 15-157° C. (shown in FIG. 6-5A and FIG. 6-7A, Ga—In phase diagram). There is a further detailed discussion about continuous latent heat absorption of phase change metal (PCM) TIMs (binary metal and ternary metal) in the paper, “Fluidic phase-change materials with continuous latent heat from theoretically tunable ternary metals for efficient thermal management”, DOI: https://doi.org/10.1073/pnas.2200223119 (shown in FIG. 6-7A, FIG. 6-7B, FIG. 6-8A, FIG. 6-8B, and FIG. 6-8C). For example, BM2 (Ga_{0.50}In_{0.50}) shows its step-cooling trend: L→L+S(In)→S(Ga)+S(In); p₁ and p₃ correspond to the solidus temperature of 15.5° C. and the liquidus temperature of 70° C. for Ga_{0.50}In_{0.50} (shown in FIG. 6-7A). It also shows a continuous phase transition (p₂ to p₃) under its melting range from 30° C. to 70° C. (shown in FIG. 6-7A) and the effective latent heat absorption (shown in FIG. 6-8B and FIG. 6-8C, BM2). Additionally, Ga—In phase change metal TIM can mix with high thermal conductivity particles (such as micro copper or diamond particles) to increase its overall thermal conductivity. On the other hand, TM (Ga_{0.40}In_{0.28}Sn_{0.32}) shows its step-cooling trend: L→L+S(Sn)→L+S(Sn)+S(In_{0.75}Sn_{0.25})→S(Sn)+S(In_{0.75}Sn_{0.25})+S(Ga); q₃ and q₁ correspond to the solidus temperature of 15.5° C. and the liquidus temperature of 70° C. for Ga_{0.50}In_{0.50} (shown in FIG. 6-7B). It also shows a continuous phase transition (q₃, to q₂, and then to q₁) under its melting range from 10° C. to 33.7° C., and to 70° C. (FIG. 6-7B) and the effective latent heat absorption (shown in FIG. 6-8B and FIG. 6-8C, TM). TM (ternary metal) has higher thermal conductivity, broader melting range and more effective latent heat than BM (binary metal). Additionally, Ga—In—Sn phase change metal (PCM) TIM also can mix with high thermal conductivity particles (such as micro copper or diamond particles) to increase its overall thermal conductivity. As phase change metal (PCM) TIM, Ga-based binary metal or ternary metal both can perform the thermal buffer effect for CPU by absorbing a significant amount heat during its transition from solid state to liquid state. The latent heat absorption started from the melting point of Gallium (around 30° C.) toward the liquidous temperature (melting point) of binary metal or ternary metal (shown in FIG. 6-8B). This continuous phase transition can buffer against (absorb and eliminate) the abrupt thermal spikes as CPU temperature is raised and helps to smooth and flat the fluctuations of CPU surface temperature. Therefore, it can reduce the occurrences of thermal throttling (hotspots) and consequently gain better performance. For better thermal management of transient thermal spikes, the liquidous temperature (melting point) of binary or ternary metal should be set as closer as possible toward Tⱼₘₐₓ (the maximum temperature in CPU before its transistors become unreliable, 85-110° C.) of CPU. According to the phase diagrams (FIG. 6-7A and FIG. 6-9), Ga—In binary metal, such as Ga_{0.25}In_{0.75} (TP2)/Ga_{0.22}In_{0.78} (TP1), and Ga—In—Sn ternary metal, such as Ga_{0.11}In_{0.49}Sn_{0.40} (C4)/Ga_{0.08}In_{0.49}Sn_{0.43} (C5), are the targeted phase change metal (PCM) TIMs with melting point (90° C. and 100° C.) closer to typical Tⱼₘₐₓ of CPU.

For better computing performance, Intel brings multiple turbo boost technologies to its CPU family (shown in FIG. 6-10A and FIG. 6-10B). Under TDP (thermal design power) or PL1 (power limit 1), CPU cores can run at base frequency forever with recommended cooling system. In TB2 (Turbo Boost 2.0), CPU cores can run at turbo frequency and power could sustain here up to serval tens seconds (Tau, time constant). For higher workload, CPU cores even can run at higher frequency than turbo frequency in few tens ms (thermal bursts), such as TBM3 (Turbo Boost Max 3.0), TVB (Thermally Velocity Boost), and ABT (Adaptive Boost Technology). In general, the overall power consumption (heat flux) of CPU is accumulated from serval thermal bursts or spikes that generated by CPU cores under different clocks(frequencies), high speed I/O, and SRAM access. Because of thermal inertia of typical cooling, CPU cannot response instantly the abrupt temperature spikes that cause by high workload and finally CPU temperature reach to the thermal threshold temperature (Tⱼₘₐₓ). Then it will trigger the thermal throttling often and result in less efficient performance of high-power density HPC applications for AI and Data Server.

IHHDS not only maximizes the heat dissipation because of its better thermal resistance but also provides direct-to-chip transient cooling capability (thermal buffer) to decrease the occurrences of hotspots. The continuous latent heat absorption of Ga-based phase change metal (PCM) TIM takes the key role to smooth and flatten the temperature fluctuations that caused by thermal spikes from bursty workloads. In other words, instant direct-to-chip cooling brought by phase change metal (PCM) TIM incorporated with IHHS helps to gain better thermal management for advanced HPC applications, esp. AI and Data server.

According to Aqwest LLC's paper and patent (refer to “Quasi-Passive Heat Sink for High-Power Laser Diodes”, https://www.researchgate.net/publication/244830019_Quasi_Passive_Heat_Sink_for_High-Power_Laser_Diodes and US20090126922A1), a tiny active liquid metal cooling loop drove by MHD (magnetohydrodynamic) pump is introduced (shown in FIG. 6-11A and FIG. 6-11B). MHD (Magnetohydrodynamic) pump is a device that takes advantage of the principles (Lorentz law) of magnetohydrodynamics (electrical and magnetic fields) to move conductive fluids, such as liquid metals or electrolytes, without any moving mechanical parts. This tiny active cooling system can dissipate ultra-high heat flux (800 W/cm²) under the heat load over 200 W because high flow velocity of liquid metal circulated in a tiny sealed and closed loop. Liquid metal flow is generated electromagnetically without any moving parts (shown in FIG. 6-11C), and flow velocity can be controlled by electrical current according to the requirement of system cooling.

Advanced semiconductor nodes technology and chip-level heterogeneous integration lead to the higher power density and more uneven temperature distribution in advanced AI accelerators (such as CPU, GPU, TPU and ASIC SoC). Moreover, the burst AI workload exacerbates the transient thermal impacts that caused by the above intrinsic factors. The more frequent thermal throttling results in much more severe performance degradation, poor service quality, and even the abrupt power fluctuations in AI computing system. The bursty nature of AI LLM workload during training and inference—sudden, unpredictable, multiple high-density power fluctuations within ultra-short duration, are beyond the cooling and thermal management of typical silicon chip. Therefore, transient thermal spikes and hotspots cause more incidence of thermal throttling.

The adaptive thermal buffer that contributed from the incorporation of Ga-based PCM TIM and supplemental active cooling (MHD pump driven) could provide solution for mitigating the above transient thermal challenges. Because MHD pump has advantage in high power efficiency and quick start time, AI/ML based workload-aware prediction algorithm may help to trigger MHD pump earlier to compensate the heat difference between bursty workload and latent heat absorption of PCM TIM (thermal buffer). To shorten the quick start time to drive the MHD pump to the maximum flow velocity, it is designed to keep the MHD pump run all the time in related slow velocity (base speed) to overcome the friction of loops inner surface. It saves time (T_{MHD,trigger}, shown in FIG. 6-12) to trigger the pump to maximum velocity.

Due to the limited volume of cavity-like containment in IHHDS, Ga-based PCM TIM (thermal buffer) only can absorb few or tens joules heat during its phase transition. To maximize the overall heat absorption capability, it is necessary to trigger MHD pump earlier toward full capability of cooling by using AI/ML based prediction. AI System can provide precise and effective prediction result of the emerging bursty workload in advance through machine-learning based workload-aware prediction algorithm and the history data of workload of AI computing and real-time hardware status (power, frequency, and temperature).

As shown in FIG. 6-12, all possible cases that trigger MHD pump are listed as below: case 0-1 and case 0-2 represent the occasions without applying AI/ML prediction; case 1-1, case 1-2, and case 1-3 represent the occasions with applying AI/ML prediction. Where T_{predict} is the lead time of burst workload happening by AI/ML prediction, T_{burst} is the duration of emerging burst workload, T_{PCM} is the duration of PCM TIM latent heat absorption, T_{MHD,trigger} is the lead time of MHD pump triggered to maximum velocity, and T_{MHD,max} is the duration of MHD pump in maximum velocity.

Without AI prediction, it is almost impossible exist in case 0-1 that T_{MHD,trigger}<T_{PCM} because limited volume of PCM TIM; and it is not helpful in case 0-2 because PCM TIM has already shifted toward liquid phase completely, no more latent heat absorption. On the other hand, it is much possible to perform the complete latent heat absorption with AI/ML prediction. As the combination and arrangement of T_{MHD,trigger} and T_{predict} in case 1-1, it can offset the partial heat burst of workload in advance and provide more headroom of latent heat absorption to flatten the temperature fluctuation that caused by bursty workload. Moreover, the burst workload may be diminished completely in case its shorter duration or not much overall heat.

Due to the continuous melting range (30° C. to melting point, shown in FIG. 6-7A and 6-7B) of Ga-based binary/ternary alloy, the temperature of PCM TIM means the fraction of partial PCM TIM melting aka the remaining heat absorption capacity. Under case 1-1, there is much broader headroom burst workload leverage to incorporate with the control of intrinsic DVFS (Dynamic Voltage and Frequency Scaling) and cooling (such as microchannel integrated heat sink) under different phases (solid, liquid, and partial solid) of PCM TIM.

The typical critical operating temperature of CPU (Tⱼₘₐₓ) is about 95-105° C. Therefore, the liquidous temperature (melting point) of phase change metal (PCM) TIM should be set as closer as Tⱼₘₐₓ then the continuous latent heat absorption can effectively impact to CPU's thermal throttling through supplemental local active cooling. Therefore, it should adjust the mixing ratio of Ga—In binary metal toward richer Indium (70%-80% weight ratio, refer to FIG. 6-7A), such as Ga_{0.25}In_{0.75} (TP2) or Ga_{0.22}In_{0.78} (TP1), then the melting range of Ga—In binary metal will be extended broader and the liquidus temperature will be raised higher (such as 90° C. or 100° C., close to Tⱼₘₐₓ). Instead, it is more complicated composition design for Ga-In-Sn ternary metal, the weight ratio of Sn is located between 40% and 43% (horizontal lines) and isothermal lines (90° C. and 100° C.) are intersected with eutectic line (E₀L, FIG. 6-9) at Ga_{0.11}In_{0.49}Sn_{0.40} (C4) and Ga_{0.08}In_{0.49}Sn_{0.43} (C5) with melting point at 90° C. and 100° C. respectively. To enhance the continuous latent heating of limited volume PCM TIM, additional tiny active liquid metal cooling loop drove by MHD pump is necessary. The activated temperature that triggers MHD pump to speed up liquid metal flow of extra active cooling loop should be set lower 10-20° C. than Tⱼₘₐₓ upon the control algorithm of thermal management. Cause more heat absorbed by thermal buffer (space), it consequently defers and reduces the occurrences of CPU thermal throttling. The flow velocity (speed) drove by MHD pump is another consideration that directly impact the flux of heat absorption. Therefore, excellent thermal management of CPU should take the above two factors (trigger temperature and flow speed) into consideration for supplemental active cooling system.

As Intel and Indium corp. mentioned, cold-pressing method is suitable for preforming the mixing of the malleable alloy (such as solid-state Ga-based alloy) or metal (such as Indium, solid state). This solid-solid mixing by cold-pressing method offers serval advantages: 1) it is simple and easy to handle for high volume manufacturing (HVM) compatible process. 2) low process temperature helps prevent oxidation, melting or deformation during processing. 3) it is good for precise control of the binary metal and ternary metal mixing ratio. As shown in FIG. 8-2, the targeted phase change metal (PCM) TIM preform (826) which is comprised of a phase change metal (PCM) alloy (825) wrapped with two thin high melting point outer metal layers (821, 10-25 umT) is formed. The surface of thin outer metal layers (821) features a micropillar pattern (822).

According to the binary metal phase diagrams (FIG. 6-7A) and composition design, there is the targeted Ga—In (Indium rich) binary metal alloy (825, also 731* in FIG. 7-3 and 931* in FIG. 9-3), such as Ga_{0.22}In_{0.78} (TP1) or Ga_{0.25}In_{0.75} (TP2), designed as pre-defined mixing ratio to match correspondent melting points (90° C. and 100° C.). The targeted PCM TIM preform (826, also 738 in FIG. 7-3 and 938 in FIG. 9-3) which is comprised of a PCM alloy (825, such as Ga_{0.22}In_{0.78} or Ga_{0.25}In_{0.75}) wrapped with two thin outer Indium layers (821, 10-25 umT, also 718* in FIG. 7-3 and 918* in FIG. 9-3) is formed. The surface of thin Indium outer layers features a micropillar pattern (822).

Ternary metals have a higher melting point and a significantly more latent heat than binary metals. However, their composition seems be more intricate and challenging to control the mixing ratio. According to the ternary metal phase diagrams (FIG. 6-9) and composition design, there is the phase change metal (PCM) alloy (825, also 731* in FIG. 7-3 and 931* in FIG. 9-3), such as Ga_{0.11}In_{0.49}Sn_{0.40} (C4) or Ga_{0.08}In_{0.49}Sn_{0.43} (C5), designed as pre-defined mixing ratio to match correspondent melting points (90° C. and 100° C.). The targeted PCM TIM preform (826, also 738 in FIG. 7-3 and 938 in FIG. 9-3) which is comprised of a PCM alloy (825, such as Ga_{0.11}In_{0.49}Sn_{0.40} or Ga_{0.08}In_{0.49}Sn_{0.43}) wrapped with two thin Sn outer layers (821, 10-25 umT, also 718* in FIG. 7-3 and 918* in FIG. 9-3) is formed. The surface of thin Sn outer layers features a micropillar pattern (822).

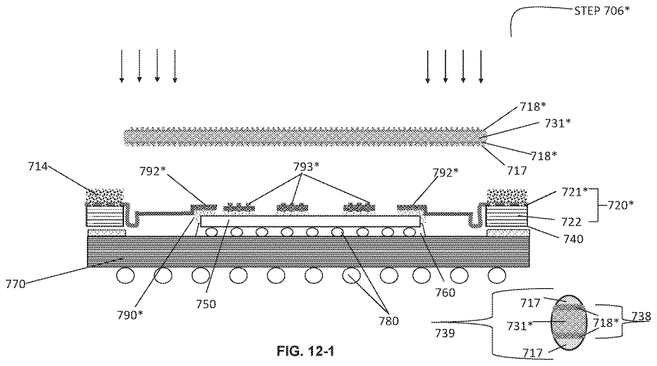

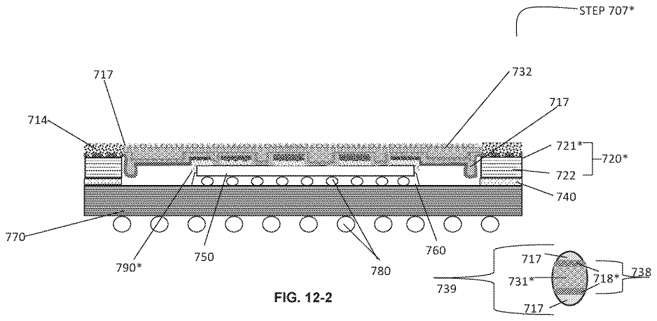

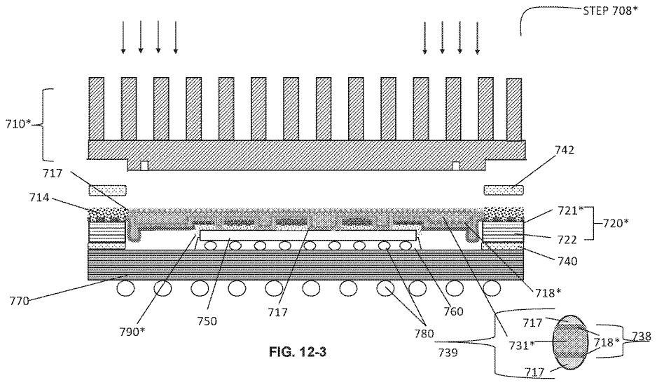

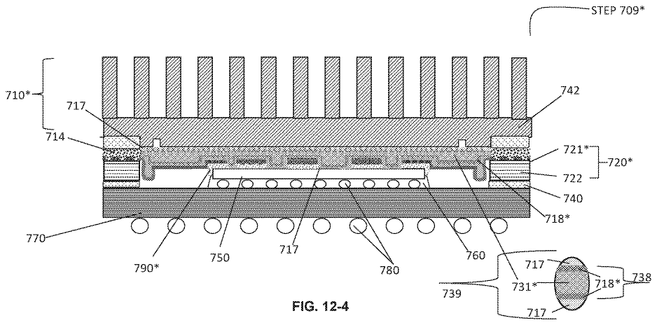

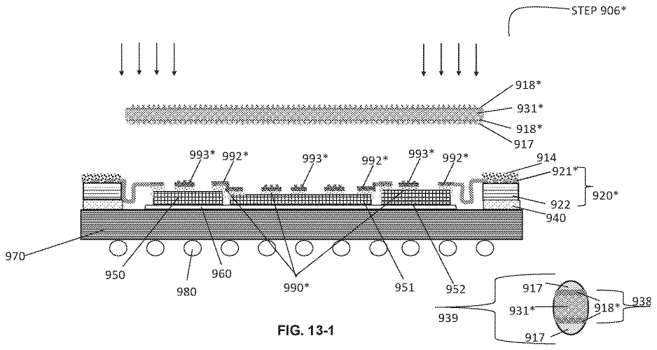

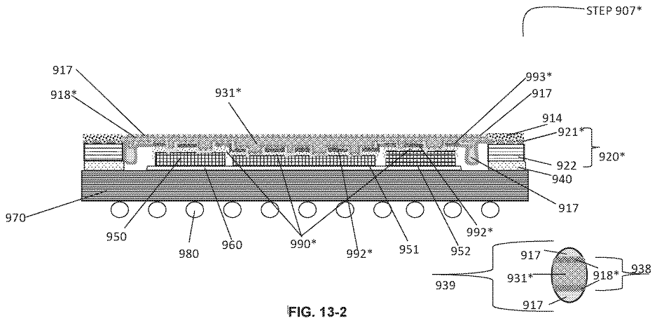

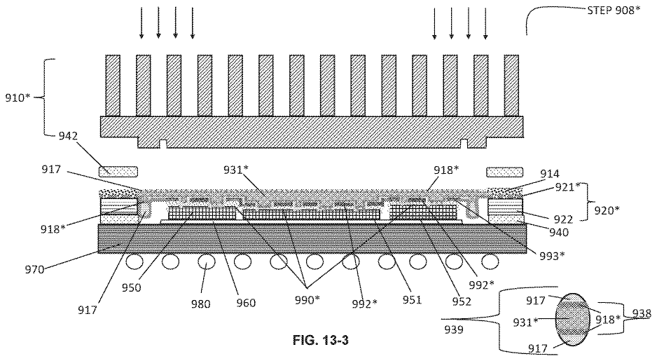

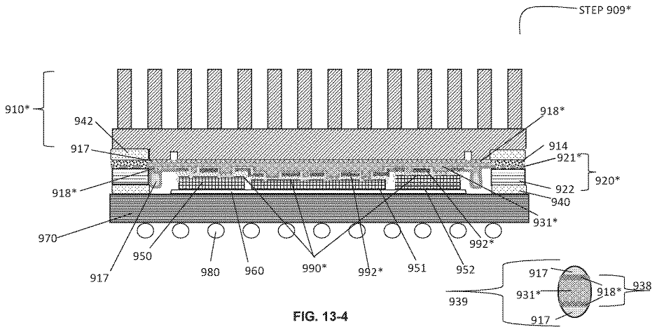

The above targeted PCM TIM preform (826, also 738 in FIG. 7-3 and 938 in FIG. 9-3) can be manufactured and integrated into high volume manufacturing (HVM) compatible process (STEP 706* in FIG. 12-6 and STEP 906* in FIG. 13-6) of forming liquid metal sandwiched PCM TIM (739 in FIG. 7-3 and 939 in FIG. 9-3). The surface of thin outer metal layer (821, 10-25 umT, also 718* in FIG. 7-3 and 918* in FIG. 9-3) features a micropillar pattern. The two thin outer metal layers (821, also 718* in FIG. 7-3 and 918* in FIG. 9-3) seal the core metal or metal alloy layer (825, also 731* in FIG. 7-3 and 931* in FIG. 9-3) firmly and prevent more advanced oxidation of Gallium in core metal alloy layer (825).

FIG. 7-3 is a schematic diagram illustrating that liquid metal sandwiched PCM TIM (739), thin liquid state Galinstan or EGaInSn (717)—thick Ga-based binary or ternary metal PCM TIM preform with double-sided micropillar patterns (738, no shown)-thin liquid-state Galinstan or EGaInSn (717), is formed and cover the top surface of the high thermal conductivity metal deposition layer (792*) and thick high thermal conductivity metal deposition layer (793*) of the silicon die (750), die-exposed area (724) and the thin flexible IHHS perforated foil (721*). The thick PCM TIM preform for Ga-based binary or ternary metal (738) can be manufactured in lab or purchased from material supplier. The cavity-like container (715, no shown) is designed to confine the liquid metal sandwiched PCM TIM (739) and seal it inside the cavity-like container without any leakage. Active cooling loops (716) coupled with MHD pumps are embedded in the main body (702) of Heat Sink (710*). Pick and place Heat Sink (710*) onto the surface of liquid metal sandwiched PCM TIM (739). Then Heat Sink (710*) is attached to the Heat Sink Supporter layer (714) by applying sealant (742) and then perform curing process onto full module and fix the Heat Sink (710*). The vents (712) of main body (702) in Heat Sink (710*) can accommodate the volume changes (expansion or shrinkage) of liquid metal TIM during thermal cycling. The new liquid metal sandwiched PCM TIM (739) with MHD pumps driven active cooling loops (716) can perform transient thermal management with thermal buffer feature during continuous phase transition. The bottom-up high-volume manufacturing (HVM) assembly procedures are exhibited as FIG. 12-6 to FIG. 12-9 for monolithic.

FIG. 7-3-1 is a schematic diagram illustrating the top view A-A′ of FIG. 7-3, active cooling loops (716) are disposed inside a main body (702) of the heat sink (710*) and distributed evenly over silicon die (750), wherein a coolant of Gallium or Galinstan inside the active cooling loops (716) is driven by MHD pumps to circulate inside the active cooling loops (716) and each of the MHD pumps is configured by two paralleled permanent magnets (736) and serval active loops coupled with DC electrodes (737). A plurality of MHD pumps is disposed inside the protrusion portion (735) of the main body (702). All active cooling loops (716) are filled a coolant of Gallium or Galinstan and inner surface of active cooling loops (716) is coated with anti-corrosion layer (such as Ni coating) to avoid the Gallium corrosion and reduce the friction during flow. Because the limited volume of phase change metal TIM for most of AI xPUs, the effective latent heat can absorb serval transient thermal spikes simultaneously. Compared with the high velocity (few meter/s) of AHS (active heat sink) for HPLD (high power laser diode) as Aqwest LLC mentioned above, the coolant inside the active cooling loops (716) driven by MHD pumps with relative slow flow velocity (less power consumption) can rapidly remove the heat from phase change metal TIM and quickly restore its phase from liquid-state to solid-state for absorption of next thermal spikes.

As exhibited in FIG. 7-3-2 (center cross section view C-C′ of FIG. 7-3), the coolant of Gallium or Galinstan inside the active cooling loops (716) flows over the silicon chip package (750). The coolant flow inside the active cooling loops (716) absorbs the heat of liquid metal sandwiched PCM TIM (739) through thin hot side (bottom) of Heat Sink (710*) toward the cold side (top) and dissipates the heat through a plurality of fins to ambient. The MHD pump moves conductive fluids, such as liquid metals or electrolytes, without any moving mechanical parts by taking advantage of the effect of electrical and magnetic fields (Lorentz law) shown in FIG. 6-8C.

As exhibited in FIG. 7-3-3 (cross section view B-B′ of the protrusion portion (735) shown in FIG. 7-3-1), active cooling loops (716) are located between two paralleled permanent magnets (736) and each active cooling loop is coupled with electrodes (737) with DC (direct current) source that controlled by thermal management system of xPUs. The flow velocity-the magnitude of DC (direct current) is programmed by thermal management system software of xPUs according to workload-aware and machine-learning bursty workload prediction algorithm. The above adaptive velocity control mechanism performs the continuous latent heat absorption for abrupt and bursty workload (such as transient thermal spikes and hotspots) to reduce the incidence of thermal throttling (performance degradation) and enhance the computing efficiency.

FIG. 9-3 is a schematic diagram illustrating that liquid metal sandwiched PCM TIM (939), thin liquid state Galinstan or EGaInSn (917)—thick Ga-based binary or ternary metal PCM TIM preform with double-sided micropillar patterns (938)—thin liquid state Galinstan or EGaInSn (917), is formed and cover the top surface of the metal deposition layer (992*) and hotspot metal deposition layer (993*) of the silicon die (950), die-exposed area (924) and the thin flexible IHHS perforated foil (921*). The thick PCM TIM preform for Ga-based binary or ternary metal (938) can be manufactured in lab or purchased from material supplier. The cavity-like container (915, no shown) is designed to confine the liquid state PCM TIM and seal it inside the cavity without any leakage. Active cooling loops (916) coupled with MHD pumps are embedded in the main body (902) of Heat Sink (910*). Pick and place Heat Sink (910*) onto the surface of liquid metal sandwiched PCM TIM (939). Then Heat Sink (910*) is attached to the Heat Sink Supporter layer (914) by applying sealant (942) and then perform curing process onto full module and fix the Heat Sink (910*). The vents (912) of main body (902) in Heat Sink (910*) can accommodate the volume changes (expansion or shrinkage) of liquid metal TIM during thermal cycling. The new liquid metal sandwiched PCM TIM (939) with MHD pumps driven the coolant inside the active cooling loops (916) can perform transient thermal management with thermal buffer feature during continuous phase transitions. The bottom-up high-volume manufacturing (HVM) assembly procedures are exhibited as FIG. 13-6 to FIG. 13-9 for chiplet heterogeneous integration.

Active cooling loops (916) are disposed inside a main body (902) of the heat sink (910*) and distributed evenly over silicon dies (950, 951, and 952), wherein a coolant of Gallium or Galinstan inside the active cooling loops (916) driven by the MHD pumps to circulate inside the active cooling loops and each of MHD pumps is configured by two paralleled permanent magnets (936) and serval active loops coupled with DC electrodes (937). A plurality of MHD pumps is disposed inside the protrusion portion (935) of the main body (902). All active cooling loops (916) are filled Gallium or Galinstan and inner surface of active cooling loops is coated with anti-corrosion layer (such as Ni coating) to avoid the Gallium corrosion and reduce the friction during flow. Because the limited volume of phase change metal TIM for most of AI xPUs, the effective latent heat can absorb serval transient thermal spikes simultaneously. Compared with the high velocity (few meter/s) of AHS (active heat sink) for HPLD (high power laser diode) as Aqwest LLC mentioned above, the coolant inside the active cooling loops (916) driven by the MHD pumps with relative slow flow velocity (less power) can rapidly remove the heat from phase change metal TIM to quick restore it from liquid-state to solid-state for absorption of next thermal spikes.

As exhibited in FIG. 9-3-1 (center cross section view C-C′ of FIG. 9-3), the coolant of Gallium or Galinstan inside the active cooling loops (916) flows over the silicon chip package. The coolant flow inside the active cooling loops (916) absorbs the heat of liquid metal sandwiched PCM TIM (939) through thin hot side (bottom) of Heat Sink (910*) toward the cold side (top) and dissipate the heat through a plurality of fins to ambient. The MHD pumps move conductive fluids, such as liquid metals or electrolytes, without any moving mechanical parts by taking advantage of the effect of electrical and magnetic fields (Lorentz law) shown in FIG. 6-8C.

As exhibited in FIG. 9-3-2 (cross section view B-B′ of the protrusion portion (935) shown in FIG. 9-3-1), active cooling loops (916) are located between two paralleled permanent magnets (936) and each active cooling loop is coupled with electrodes (937) with DC (direct current) source that controlled by thermal management system of xPUs. The flow velocity—the magnitude of DC (direct current) is programmed by thermal management system (firmware) of xPUs according to workload-aware and machine-learning burst workload prediction algorithm. The above adaptive velocity control mechanism performs the continuous latent heat absorption for abrupt and bursty workload (such as transient thermal spikes and hotspots) to reduce the incidence of thermal throttling (performance degradation) and enhance the computing efficiency.

In FIG. 10-1, STEP 701 exhibits the deposition process of Heat Sink Supporter (714). First, deposit Heat Sink Supporter (714) onto the IHHS foil Supporter (722) through thin flexible IHHS perforated foil (721*) by deposition of cold spray additive manufacturing. The particles inject from cold spray additive manufacturing can penetrate the flexible IHHS perforated foil (721*) and thus secure the flexible IHHS perforated foil (721*) in hermetic manner to the IHHS foil Supporter (722). This forms the Heat Sink Supporter layer (714) on top of the thin flexible IHHS perforated foil (721*) in order to form a one-piece frame module (700) including the thin flexible IHHS perforated foil (721*), Heat Sink Supporter layer (714), and IHHS foil Supporter (722), as shown in FIG. 10-2, STEP 702.

Referring to FIG. 10-3, in STEP 703, a thin metal deposition base layer (790* as submicron buffer layer, around 1 umT) is attached onto the silicon die (750) through fine metal mask (758) by deposition of cold spray additive manufacturing. The metal deposition base layer (790*) such as aluminum material or PVD adhesive layer can adsorb impact from later thick metal layer deposition by cold spray additive manufacturing.

Referring to FIG. 10-4, in STEP 704, the one-piece frame module (700) is properly attached onto top of silicon die (750), which is deposit with the metal base layer (790*) using die attaching and fixing mechanism (728). Meanwhile, one-piece frame module is also attached to substrate (770) with sealant (740).

Referring to FIG. 10-5-1, in STEP 705, a metal deposition layer (792*, not shown) of thickness about 25-50 um is then deposited onto the top position of the one-piece frame module (700), corresponding to the position of the silicon die (750) through fine metal mask (758) by using cold spray additive manufacturing.

Referring to FIG. 10-5-2, in STEP 705*, a hotspot metal deposition layer (793*, not shown) of thickness about 100-150 um is then deposited onto the top position the metal deposition layer (792*, not shown), corresponding to the hotspots of the silicon die (750) through fine metal mask (759) by using cold spray additive manufacturing.

Referring to FIG. 10-6, in STEP 706, a thick Indium Preform with double-sided micropillar patterns (718) is immersed with liquid state Galinstan or EGaInSn (717) through a dipping process. The Preform is then attached to silicon die (750) and an IHHS foil (721*). It covers the top surface of the metal deposition layer (792*) and hotspot metal deposition layer (793*) of the silicon die (750), die-exposed area (742) and the thin flexible IHHS perforated foil (721*).

Referring to FIG. 10-7, in STEP 707, a thin liquid state Galinstan or EGaInSn (717) is applied to the top surface of the micropillar patterned Indium Preform (718) using methods such as dispensing, jetting or scrubbing.

Referring to FIG. 10-8 in STEP 708, and FIG. 10-9 in STEP 709, Heat Sink (710) is attached to the Heat Sink Supporter layer (714) by applying sealant (742) and then perform curing process onto full module and fix the Heat Sink (710). The liquid metal sandwiched TIM (730*), thin EGaInSn or Galinstan layer (717)—Indium Preform with double-sided micropillar patterns (718)—thin EGaInSn or Galinstan layer (717) is located between Heat Sink (710) and silicon die (750).

In FIG. 11-1, STEP 901 exhibits the process to hermetically bond Heat Sink Supporter layer (914). First, deposit Heat Sink Supporter (914) onto the IHHS foil Supporter (922) through thin flexible IHHS perforated foil (921*) by deposition of cold spray additive manufacturing. The particles injected from cold spray additive manufacturing can penetrate the flexible IHHS perforated foil (921*) and thus secure the flexible IHHS perforated foil (921*) in hermetic manner to the IHHS foil Supporter (922). This forms the Heat Sink Supporter layer (914) on top of the thin flexible IHHS perforated foil (921*) in order to form a one-piece frame module (900) including the thin flexible IHHS perforated foil (921*), Heat Sink Supporter layer (914), and IHHS foil Supporter (922), as shown in FIG. 11-2, STEP 902.

Referring to FIG. 11-3-1, FIG. 11-3-2, and FIG. 11-3-3, in STEP 903-1, STEP 903-2, and STEP 903-3, a thin metal deposition base layer (990* as submicron buffer layer, around 1 umT) is attached onto the silicon dies (950, 951, and 952) through fine metal masks (958-1, 958-2, and 958-3) by deposition of cold spray additive manufacturing correspondingly. The metal deposition base layer (990*) such as aluminum material or PVD adhesive layer can adsorb impact from later thick metal layer deposition by cold spray additive manufacturing.

Referring to FIG. 11-4, in STEP 904, the one-piece frame module (900) is properly attached onto top of silicon dies (950, 951, and 952) which are deposit with the metal base layer (990*) using die attaching and fixing mechanism (928). Meanwhile, one-piece frame module is also attached to substrate (970) with sealant (940).

Referring to FIG. 11-5-1, FIG. 11-5-1a, FIG. 11-5-2, FIG. 11-5-2a, FIG. 11-5-3, and FIG. 11-5-3A in STEP 905-1, STEP 905-1*, STEP 905-2, STEP 905-2*, STEP 905-3, and STEP 905-3*, a metal deposition layer (992*, not shown) of thickness about 25-50 μm is then deposited onto the top position of the one-piece frame module, corresponding to the position of the silicon dies (950, 951, and 952) through fine metal masks (958-1, 958-2, and 958-3) by using cold spray additive manufacturing. Then a hotspot metal deposition layer (993*, not shown) of thickness about 100-150 μm is then deposited onto the top position of the one-piece frame module, corresponding to the position of the silicon dies (950, 951, and 952) through fine metal masks (959-1, 959-2, and 959-3) by deposition of cold spray additive manufacturing.

Referring to FIG. 11-6, in STEP 906, a thick Indium Preform with double-sided micropillar patterns (918) is immersed with liquid state Galinstan or EGaInSn (917) through a dipping process. The Preform is then attached to silicon dies (950, 951 and 952) and an IHHS foil (921*). It covers the top surface of the metal deposition layer (992*) and hotspot metal deposition layer (993*) of silicon dies (950, 951, and 952), die-exposed area (942) and the thin flexible IHHS perforated foil (921*).

Referring to FIG. 11-7, in STEP 907, a thin liquid state Galinstan or EGaInSn (917) is applied to the top surface of the micropillar patterned Indium Preform (918) using methods such as dispensing, jetting or scrubbing.

Referring to FIG. 11-8 in STEP 908, and FIG. 11-9 in STEP 909, Heat Sink (910) is attached to the Heat Sink Supporter layer (914) by applying sealant (942) and then perform curing process onto full module and fix the Heat Sink (910). The liquid metal sandwiched TIM (930*), thin EGaInSn or Galinstan layer (917)—Indium Preform with double-sided micropillar patterns (918)—thin EGaInSn or Galinstan layer (917) is located between Heat Sink (910) and silicon dies (950, 951, and 952).

Referring to FIG. 12-6 in STEP 706*, thick PCM TIM preform for Ga-based binary or ternary metal with double-sided micropillar patterns (738) is immersed with liquid state Galinstan or EGaInSn (717) through a dipping process and the PCM TIM preform (738) is then attached to silicon die (750) and an IHHS foil (721*).

Referring to FIG. 12-7, in STEP 707*, a thin liquid state Galinstan or EGaInSn (717) is applied to the top surface of the micropillar patterned PCM TIM Preform (738) using methods such as dispensing, jetting or scrubbing.

Referring to FIG. 12-8 in STEP 708*, and FIG. 12-9 in STEP 709*, Heat Sink (710*) with active cooling loops (716) is attached to the Heat Sink Supporter layer (714) by applying sealant (742) and then perform curing process onto full module and fix the Heat Sink (710*). Then the liquid metal sandwiched PCM TIM (739), thin liquid state Galinstan or EGaInSn (717)—thick PCM TIM preform for Ga-based binary or ternary metal with double-sided micropillar patterns (738)—thin liquid state Galinstan or EGaInSn (717), is formed accordingly.

Referring to FIG. 13-6, in STEP 906*, thick PCM TIM preform for Ga-based binary or ternary metal with double-sided micropillar patterns (938) is immersed with liquid state Galinstan or EGaInSn (917) through a dipping process. The Preform is then attached to silicon dies (950, 951, and 952) and an IHHS foil (921*).

Referring to FIG. 13-7, in STEP 907*, a thin liquid state Galinstan or EGaInSn (917) is applied to the top surface of the micropillar patterned PCM TIM preform (938) using methods such as dispensing, jetting or scrubbing.

Referring to FIG. 13-8 in STEP 908*, and FIG. 13-9 in STEP 909*, Heat Sink (910*) with active cooling loops (916) is attached to the Heat Sink Supporter layer (914) by applying sealant (942) and then perform curing process onto full module and fix the Heat Sink (910*). Then the liquid metal sandwiched PCM TIM (939), thin liquid state Galinstan or EGaInSn (917)—thick PCM TIM preform for Ga-based binary or ternary metal with double-sided micropillar patterns (938)—thin liquid state Galinstan or EGaInSn (917), is formed accordingly.

It will become apparent to those people skilled in the art that various modifications and variations can be made to the structure of the disclosure without departing from the scope or spirit of the disclosure. In view of the foregoing description, it is intended that all the modifications and variation fall within the scope of the following appended claims and their equivalents.

What is claimed is:

1. A semiconductor package, comprising:
a silicon die mounted on a substrate, the silicon die having a plurality of hot spot areas and a maximum operational temperature (Tⱼₘₐₓ) thereof;
an integrated hybrid heat spreader including a thin flexible perforated foil and a supporter, wherein
the thin flexible perforated foil includes a central exposed die through area, a silicon die bonding through area, a die attaching and fixing mechanism, a curve-shaped thermal-induced stress absorbing mechanism on its lateral ends and a supporter bonding through area,
the central exposed die through area and the silicon die bonding through area are provided with a plurality of tiny holes therethrough, and
the central exposed die through area includes link-and-support stripes for connecting with the silicon die bonding through area, hotspot contact-and-link stripes extending from the silicon die bonding through area to cover the top of the plurality of hot spot areas of the silicon die, and the die-exposed area;
a first metal deposition layer cold-sprayed onto the top position of the silicon die corresponding to the link-and-support stripes, the silicon die bonding through area and the hotspot contact-and-link stripes;
a second metal deposition layer deposited onto the link-and-support stripes, the silicon die bonding through area and the hotspot contact-and-link stripes by using cold spray additive manufacturing for bonding with the first metal deposition layer through the tiny through holes in the link-and-support stripes, the silicon die bonding through area and the hotspot contact-and-link stripes;
a third metal deposition layer deposited onto the second metal deposition layer on the plurality of hotspot contact-and-link stripes at the positions corresponded with hot spot areas of the silicon die;
a heat sink fixed and attached to the heat sink supporter, wherein the heat sink, the integrated hybrid heat spreader and the exposed major portion of the die together define a hermetic cavity-like container portion;
a liquid metal sandwiched thermal interface material (TIM) disposed in between the cavity-like container portion, wherein the liquid metal sandwiched thermal interface material (TIM) includes:
a thick core layer having a first melting point much greater than the maximum operational temperature (Tⱼₘₐₓ) of the silicon die;
wherein the upper surface and the lower surface of the thick core layer are provided with a micropillar pattern;
a first layer of gallium-based liquid metal alloy applied between the lower surface of the liquid metal sandwiched thermal interface material (TIM) and the silicon die; and
a second layer of gallium-based liquid metal alloy applied between the upper surface of the liquid metal sandwiched thermal interface material (TIM) and the heat sink.

2. The semiconductor package as claimed in claim 1, wherein the first layer and the second layer of gallium-based liquid metal alloy are consisting essentially of EGaInSn or Galinstan with 2 μm thickness.

3. The semiconductor package as claimed in claim 1, wherein the first metal deposition layer is made of alumina or PVD adhesive layer of thickness less than 1 μm.

4. The semiconductor package as claimed in claim 1, wherein the second metal deposition layer is made of copper of thickness about 20-50 μm.

5. The semiconductor package as claimed in claim 1, wherein the third metal deposition layer is made of copper of thickness about 125-150 μm.

6. The semiconductor package as claimed in claim 1, wherein the thick core layer is made of Indium preform with thickness about 200-250 μm and the micropillar pattern is about 2 μm in its height.

7. The semiconductor package as claimed in claim 1, wherein
the heat sink further comprises:
a main body with a protrusion portion;
a plurality of magnetohydrodynamic pumps disposed inside the protrusion portion; and
a plurality of active cooling loops distributed evenly above silicon die and a coolant of Gallium or Galinstan inside the active cooling loops driven by the magnetohydrodynamic pumps to circulate inside the active cooling loops;
wherein the silicon die includes a thermal management software configured to
keep the MHD pump run in related slow velocity (base speed) to overcome the friction of loops inner surface; and
control the magnitude of DC (direct current) of the magnetohydrodynamic pumps for the flow velocity of the Gallium or Galinstan inside the active cooling loops according to a workload-aware and machine-learning burst workload prediction algorithm,
thereby providing more headroom of latent heat absorption to flatten the temperature fluctuations that caused by burst workload and shortening the quick start time to drive the MHD pumps to the maximum flow velocity.

8. A liquid metal sandwiched thermal interface material (TIM) configured to smooth rapid temperature fluctuation that led to thermal throttling of the silicon die, comprising:
a core layer of phase change metal alloy having a first melting point near (close but not above) a maximum operational temperature (Tⱼₘₐₓ) of the silicon die;
an upper thin outer metal layer and a lower thin outer metal layer wrapping the core layer of phase change metal alloy, the upper and lower thin outer metal layers having a second melting point much higher than maximum operational temperature (Tⱼₘₐₓ) of the silicon die; and
wherein the outer mating surfaces of the upper and lower thin outer metal layers are provided with micropillar patterns,
a first layer of gallium-based liquid metal alloy applied between the bottom surface of lower outer metal layer and the silicon die; and
a second layer of gallium-based liquid metal alloy applied between the top surface of upper outer metal layer and the heat sink.

9. The liquid metal sandwiched thermal interface material (TIM) as claimed in claim 8, wherein the core layer of phase change metal alloy is consisting essentially of Ga—In binary metal and the upper and lower thin outer metal layers are made of Indium.

10. The liquid metal sandwiched thermal interface material (TIM) as claimed in claim 8, wherein the core layer of phase change metal alloy is consisting essentially of Ga—In—Sn ternary metal and the upper and lower thin outer metal layers are made of Sn.

11. The liquid metal sandwiched thermal interface material (TIM) as claimed in claim 8, wherein the first layer and the second layer of gallium-based liquid metal alloy are consisting essentially of EGaInSn or Galinstan with 2 μm thickness.

12. A method for assembling a semiconductor package, comprising the following steps:
mounting a silicon die on a substrate, wherein the silicon die having a plurality of hot spot areas and a maximum operational temperature (Tⱼₘₐₓ) thereof;
providing an integrated hybrid heat spreader including a thin flexible perforated foil and a supporter, wherein
the thin flexible perforated foil has a central exposed die through area, a silicon die bonding through area, a die attaching and fixing mechanism, a curve-shaped thermal-induced stress absorbing mechanism on its lateral ends and a supporter bonding through area,
the central exposed die through area and the silicon die bonding through area are provided with a plurality of tiny holes therethrough, and
the central exposed die through area includes link-and-support stripes for connecting with the silicon die bonding through area, hotspot contact-and-link stripes extending from the silicon die bonding through area to cover the top of the plurality of hot spot areas of the silicon die, and the die-exposed area;
cold-spraying a first metal deposition layer onto the top position of the silicon die corresponding to the link-and-support stripes, the silicon die bonding through area and the hotspot contact-and-link stripes;
attaching the integrated hybrid heat spreader on the silicon die and the substrate;
cold spraying a second metal deposition layer onto the link-and-support stripes, the silicon die bonding through area and the hotspot contact-and-link stripes for bonding with the first metal deposition layer through the tiny through holes in the link-and-support stripes, the silicon die bonding through area and the hotspot contact-and-link stripes;
cold spraying a third metal deposition layer onto the second metal deposition layer on the plurality of hotspot contact-and-link stripes at the hot spot areas of the silicon die;
disposing a liquid metal preform sandwiched structure on the second metal deposition layer, wherein the liquid metal preform sandwiched structure includes:
a core layer of phase change metal alloy having a first melting point near (close but not above) a maximum operational temperature (Tⱼₘₐₓ) of the silicon die;
an upper thin outer metal layer and a lower thin outer metal layer wrapping the core layer of phase change metal alloy, the upper and lower thin outer metal layers having a second melting point much higher than maximum operational temperature (Tⱼₘₐₓ) of the silicon die; and
wherein the outer mating surfaces of the upper and lower thin outer metal layers are provided with micropillar patterns.
applying a first layer of gallium-based liquid metal alloy between the lower surface of the thin outer metal layer and the silicon die;
applying a second layer of gallium-based liquid metal alloy between the upper surface of the thin outer metal layer and the heat sink; and
fixing a heat sink to the heat sink supporter, wherein the heat sink, the integrated hybrid heat spreader and the exposed major portion of the die together define a hermetic cavity-like container portion.

13. The method as claimed in claim 12, wherein the first layer and the second layer of gallium-based liquid metal alloy are consisting essentially of EGaInSn or Galinstan.

14. The method as claimed in claim 12, wherein the first metal deposition layer is made of alumina or PVD adhesive layer of thickness less than 1 μm.

15. The method as claimed in claim 12, wherein the second metal deposition layer is made of copper of thickness about 20-50 μm.

16. The method as claimed in claim 12, wherein the third metal deposition layer is made of copper of thickness about 125-150 μm.

17. The method as claimed in claim 12, wherein the core layer of phase change metal alloy has a thickness about 200-250 μm.

18. The method as claimed in claim 12, further comprising:
providing a plurality of magnetohydrodynamic pumps inside the heat sink;
providing a plurality of active cooling loops distributed evenly over silicon die;
providing a coolant of Gallium or Galinstan inside the active cooling loops and the coolant of Gallium or Galinstan is driven by the magnetohydrodynamic pumps to circulate inside the active cooling loops;
providing a thermal management software configured to:
keep the MHD pump run in related slow velocity (base speed) to overcome the friction of loops inner surface; and
control the magnitude of DC (direct current) of the magnetohydrodynamic pumps for the flow velocity of the Gallium or Galinstan inside the active cooling loops according to a workload-aware and machine-learning burst workload prediction algorithm,
thereby providing more headroom of latent heat absorption to flatten the temperature fluctuations that caused by burst workload and shortening the quick start time to drive the MHD pumps to the maximum flow velocity.

19. The method as claimed in claim 12, wherein the liquid metal sandwiched TIM is immersed with liquid state Galinstan or EGaInSn by dipping and then attached toward silicon die and IHHS.

20. The method as claimed in claim 12, wherein a thin liquid state Galinstan or EGaInSn is jetted or scrubbed onto the top of micropillar patterns of the liquid metal preform sandwiched structure.
